(19) United States
(12) Patent Application Publication
(10) Pub. No.: US 2026/0198067 A1
(43) Pub. Date: Jul. 9, 2026

(54) SEMICONDUCTOR STRUCTURE AND METHOD FOR FORMING THE SAME

(71) Applicant: TAIWAN SEMICONDUCTOR MANUFACTURING COMPANY, LTD., Hsinchu (TW)

(72) Inventors: Jia-Chuan YOU, Taoyuan City (TW); Chu-Yuan HSU, Taichung City (TW); Chia-Hao CHANG, Hsinchu City (TW); Kuo-Cheng CHIANG, Zhubei City (TW); Chih-Hao WANG, Baoshan Township (TW)

(73) Assignee: TAIWAN SEMICONDUCTOR MANUFACTURING COMPANY, LTD., Hsinchu (TW)

(21) Appl. No.: 19/195,906

(22) Filed: May 1, 2025

Related U.S. Application Data
(60) Provisional application No. 63/742,554, filed on Jan. 7, 2025.

(51) Int. Cl. H10D 84/01; H10D 64/23; H10D 84/83

(52) U.S. Cl. CPC H10D 84/0151; H10D 64/258; H10D 84/0149; H10D 84/8312; H10D 84/8316; H10D 84/832

(57) ABSTRACT

A semiconductor structure is provided. The semiconductor structure includes a first source/drain feature over a first fin element, a second source/drain feature over a second fin element and a first gate stack and a second gate stack across the first fin element and the second fin element. The semiconductor structure further includes a dielectric layer covering the second source/drain feature and the first source/drain feature, an isolation feature interposed between the first source/drain feature and the second source/drain feature, and between the first gate stack and the second gate stack. The semiconductor structure further includes a contact structure in the dielectric layer and electrically coupled to the first source/drain feature by way of a silicide layer.

### PRIORITY CLAIM

This application claims the benefit of U.S. Provisional Application No. 63/742,554 filed on Jan. 7, 2025 and entitled “SEMICONDUCTOR DEVICE WITH CUTTING FEATURE AND METHOD FOR FORMING THE SAME,” which is incorporated herein by reference.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with related complementary metal-oxide-semiconductor (CMOS) processes, and their structure allows them to be aggressively scaled-down while maintaining gate control and mitigating SCEs. GAA devices provide a channel in a silicon nanowire/nanosheet. However, integration of fabrication of the GAA features around the nanowire/nanosheet can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIGS. 2A, 2A-1, 2A-2 and 2A-3 are schematic views illustrating the formation of a semiconductor structure at one of the intermediate stages, in accordance with some embodiments.

FIGS. 2B-1, 2B-2 and 2B-3 are schematic views illustrating the formation of a semiconductor structure at one of the intermediate stages, in accordance with some embodiments.

FIGS. 2C-1, 2C-2, 2C-3 and 2C-4 are schematic views illustrating the formation of a semiconductor structure at one of the intermediate stages, in accordance with some embodiments.

FIGS. 2D-1, 2D-2 and 2D-3 are schematic views illustrating the formation of a semiconductor structure at one of the intermediate stages, in accordance with some embodiments.

FIGS. 2E, 2E-1, 2E-2 and 2E-3 are schematic views the formation a semiconductor structure at one of the intermediate stages, in accordance with some embodiments.

FIGS. 2F-1, 2F-2, 2F-3 and 2F-4 are schematic views illustrating the formation of a semiconductor structure at one of the intermediate stages, in accordance with some embodiments.

FIGS. 2G, 2G-1, 2G-2 and 2G-3 are schematic views illustrating the formation of a semiconductor structure at one of the intermediate stages, in accordance with some embodiments.

FIGS. 2H, 2H-1, 2H-2, 2H-3 and 2H-4 are schematic views illustrating the formation of a semiconductor structure at one of the intermediate stages, in accordance with some embodiments.

FIGS. 2I-1, 2I-2, 2I-3 and 2I-4 are schematic views illustrating the formation of a semiconductor structure at one of the intermediate stages, in accordance with some embodiments.

FIGS. 2J, 2J-1, 2J-2, 2J-3 and 2J-4 are schematic views illustrating the formation of a semiconductor structure at one of the intermediate stages, in accordance with some embodiments.

FIGS. 2K, 2K-1, 2K-2 and 2K-3 are schematic views illustrating the formation of a semiconductor structure at one of the intermediate stages, in accordance with some embodiments.

FIG. 2K-4 is an enlarged view of FIG. 2K-3, in accordance with some embodiments.

FIGS. 3A and 3B are modifications of the semiconductor structure of FIG. 2K-3, in accordance with some embodiments.

FIGS. 4A and 4A-1 are schematic views illustrating a semiconductor structure, in accordance with some embodiments.

FIG. 4B is a schematic view illustrating the formation of a semiconductor structure at one of the intermediate stages, in accordance with some embodiments.

FIG. 4C is a schematic view illustrating the formation of a semiconductor structure at one of the intermediate stages, in accordance with some embodiments.

FIGS. 5A and 5B are cross-sectional view illustrating the formation of a semiconductor structure at various intermediate stages, in accordance with some embodiments.

FIGS. 6A and 6B are cross-sectional view illustrating the formation of a semiconductor structure at various intermediate stages, in accordance with some embodiments.

FIGS. 7A and 7B are cross-sectional view illustrating the formation of a semiconductor structure at various intermediate stages, in accordance with some embodiments.

FIG. 8 is a modification of the semiconductor structure of FIG. 7B, in accordance with some embodiments.

FIGS. 9A and 9A-1 are schematic view illustrating the formation of a semiconductor structure at one of the intermediate stages, in accordance with some embodiments.

FIGS. 9B and 9B-1 are schematic view illustrating the formation of a semiconductor structure at one of the intermediate stages, in accordance with some embodiments.

FIGS. 10A, 10B and 10C are cross-sectional view illustrating the formation of a semiconductor structure at various intermediate stages, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The nanostructure transistor (e.g., nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure and a method for forming the semiconductor structure are provided. The semiconductor structure includes an isolation feature which may separate adjacent source/drain features from each other. Therefore, the scaling of the spacing between adjacent active regions may not be limited by the lateral growth of the source/drain features, and thus continuously scaling down the cell height of the semiconductor devices may be achieved without degrading the manufacturing yield of the semiconductor devices.

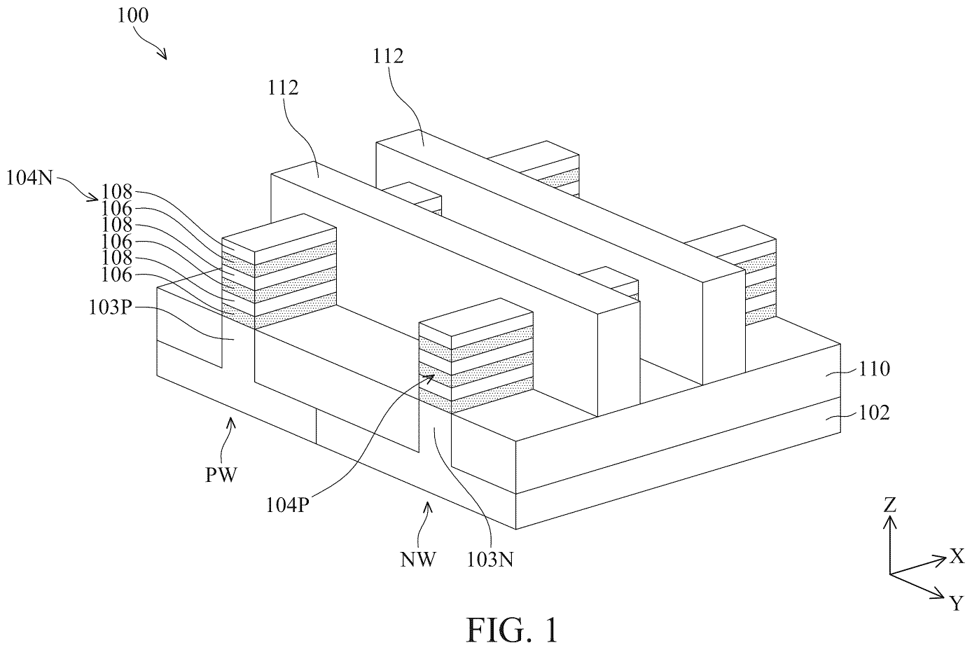

FIG. 1 is a perspective view of a semiconductor structure 100, in accordance with some embodiments. The semiconductor structure 100 includes a substrate 102 and fin structures 104 (including 104N and 104P) over the substrate 102, as shown in FIG. 1, in accordance with some embodiments. The substrate 102 includes a p-type well PW and an n-type well NW immediately adjacent to the p-type well PW, in accordance with some embodiments. The fin structure 104N is formed in the p-type well PW, and the fin structure 104P is formed in the n-type well NW, in accordance with some embodiments. The fin structures 104N and 104P are the active regions of the semiconductor structure 100, in accordance with some embodiments.

For a better understanding of the semiconductor structure 100, the X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The fin structure 104N includes a lower fin element 103P formed from the p-type well PW, and the fin structure 104P includes a lower fin element 103N formed from the n-type well NW, in accordance with some embodiments. The lower fin elements 103P and 103N are surrounded by an isolation structure 110, in accordance with some embodiments.

Each of the fin structures 104N and 104P further includes an upper fin element formed from an epitaxial stack including alternating first semiconductor layers 106 and second semiconductor layers 108, in accordance with some embodiments. The second semiconductor layers 108 will form nanostructures (e.g., nanowires or nanosheets) and serve as the channel for the resulting semiconductor devices, in accordance with some embodiments.

The fin structures 104N and 104P extend in the X direction, in accordance with some embodiments. That is, the fin structures 104N and 104P have longitudinal axes parallel to the X direction, in accordance with some embodiments. The X direction may also be referred to as the channel-extending direction. The current of the resulting semiconductor device (i.e., nanostructure transistor) flows in the X direction through the channel. Each of the fin structures 104N and 104P is defined as several channel regions and several source/drain regions, where the channel regions and the source/drain regions are arranged in an alternating manner, in accordance with some embodiments. In this disclosure, source/drain region(s) may refer to a source or a drain, individually or collectively dependent upon the context.”

Gate structures 112 are formed with longitudinal axes parallel to the Y direction and extending across and/or surrounding the channel regions of the fin structures 104N and 104P, in accordance with some embodiments. The source/drain regions of the fin structures 104N and 104P are exposed from the gate structures 112, in accordance with some embodiments. The Y direction may also be referred to as a gate-extending direction.

Although two fin structures 104 and two gate structures 112 are illustrated in FIG. 1, the semiconductor structure 100 is not intended to be limiting. The number of fin structures and the gate structures may be dependent on the design demand of an integrated circuit and/or performance consideration of resulting semiconductor devices.

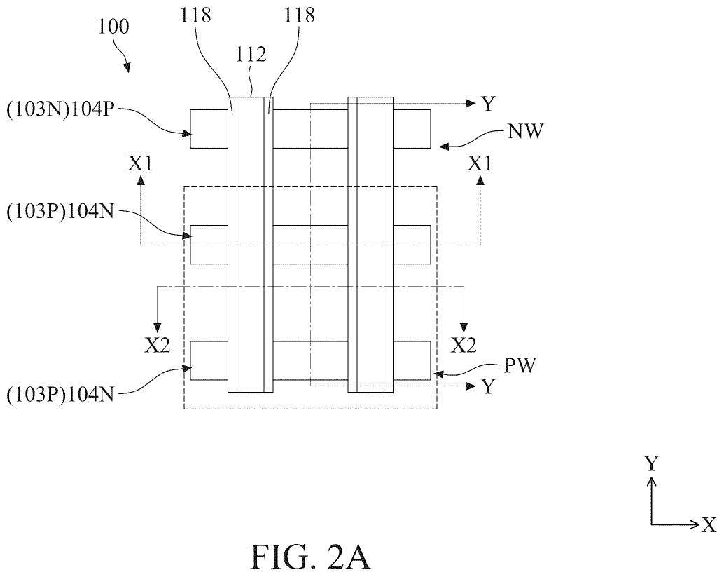

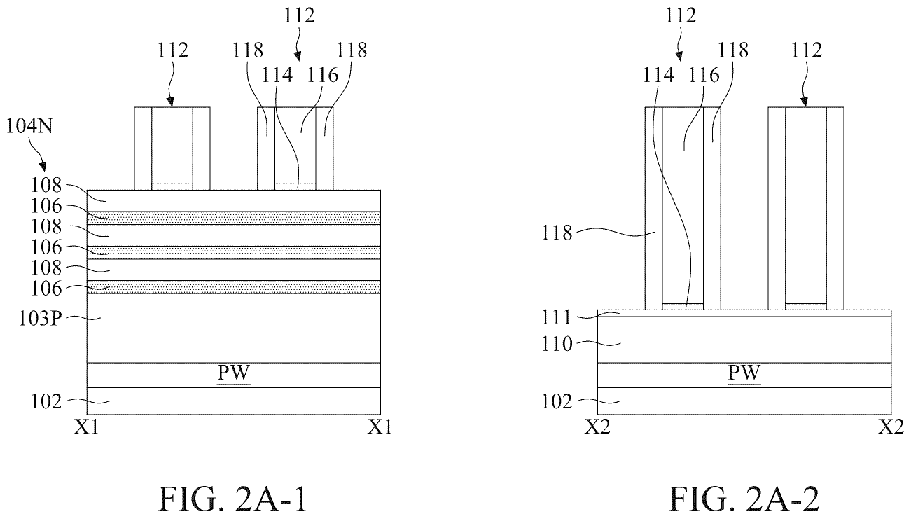

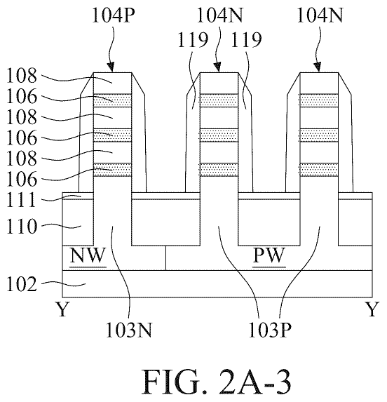

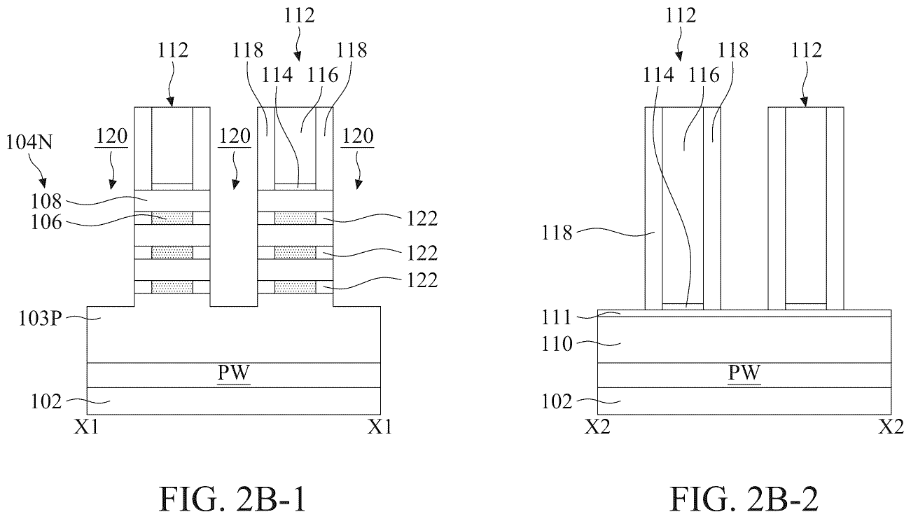

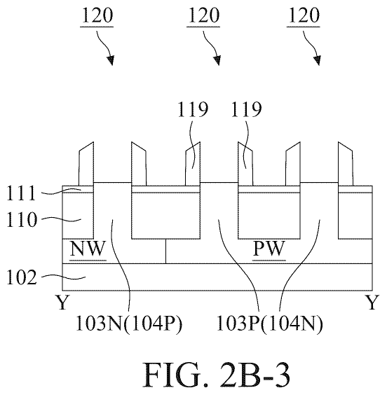

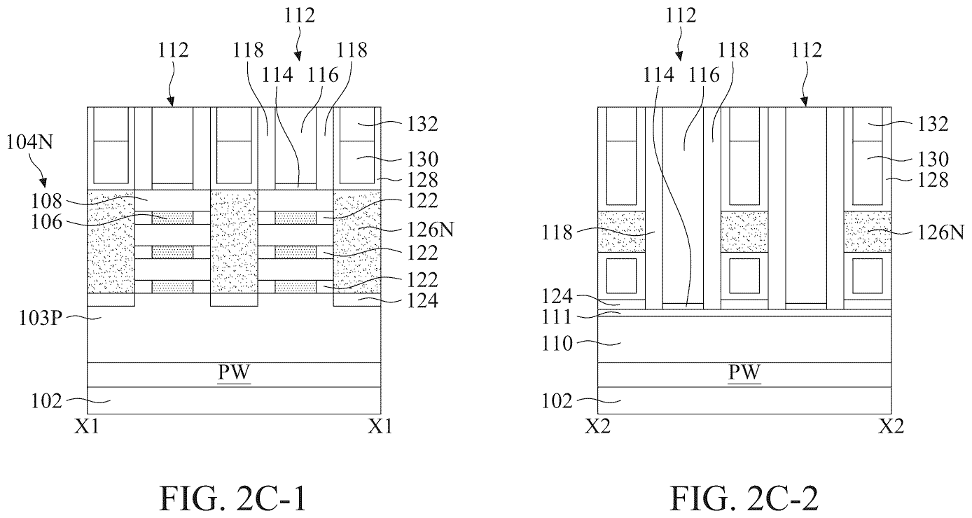

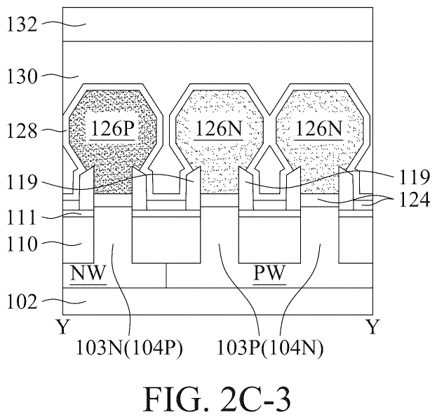

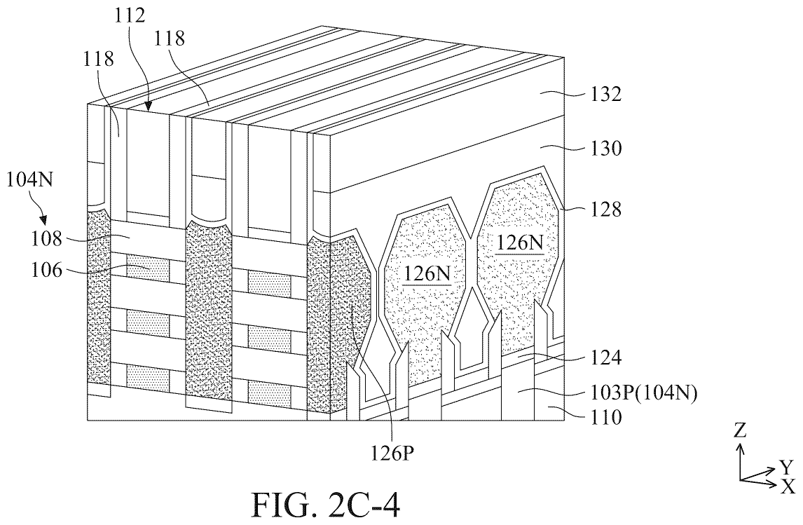

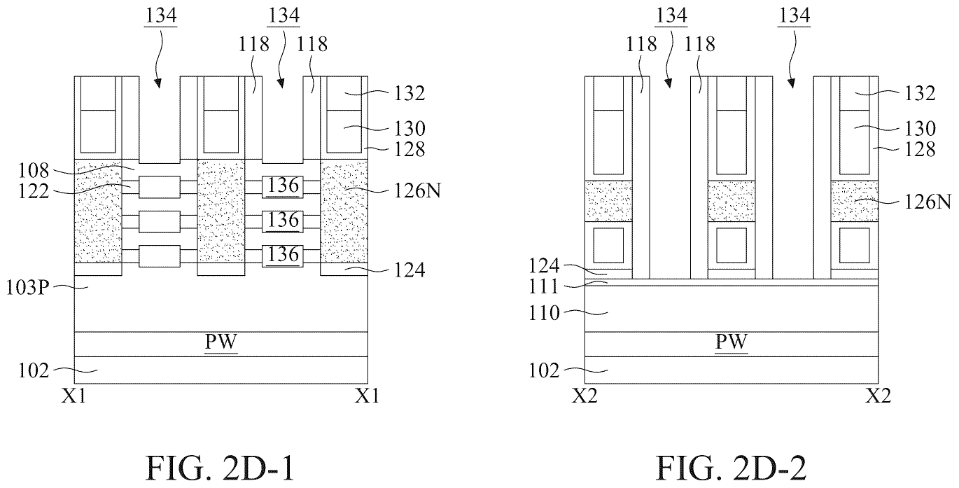

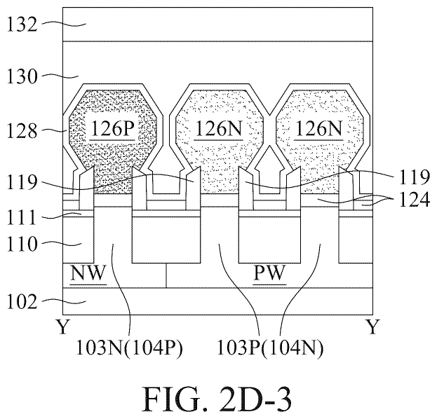

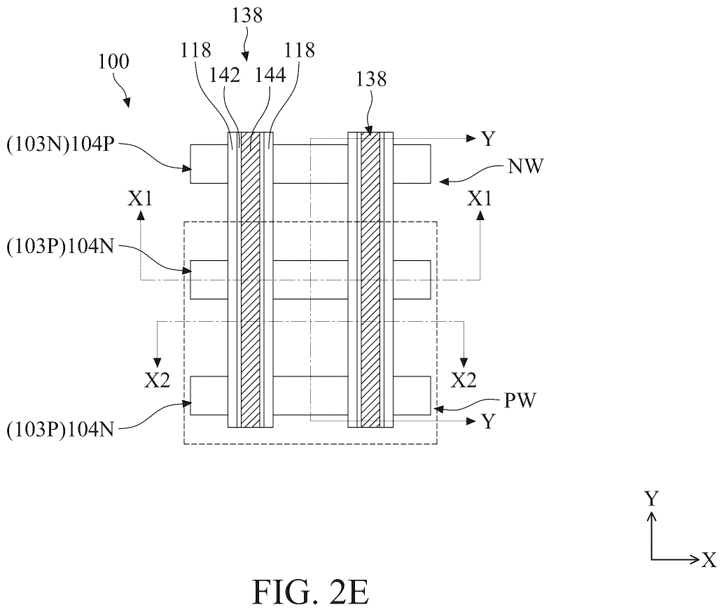

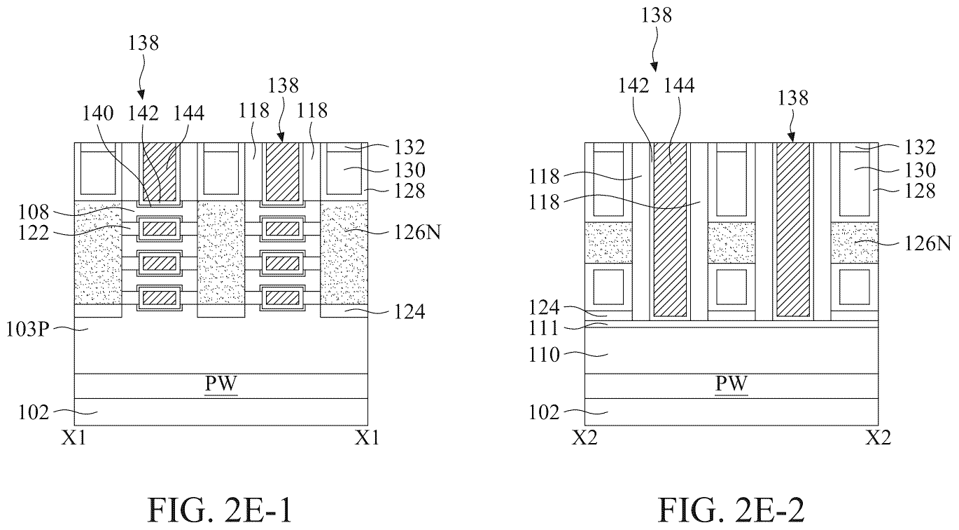

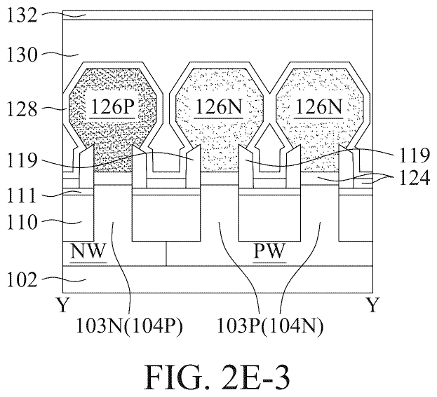

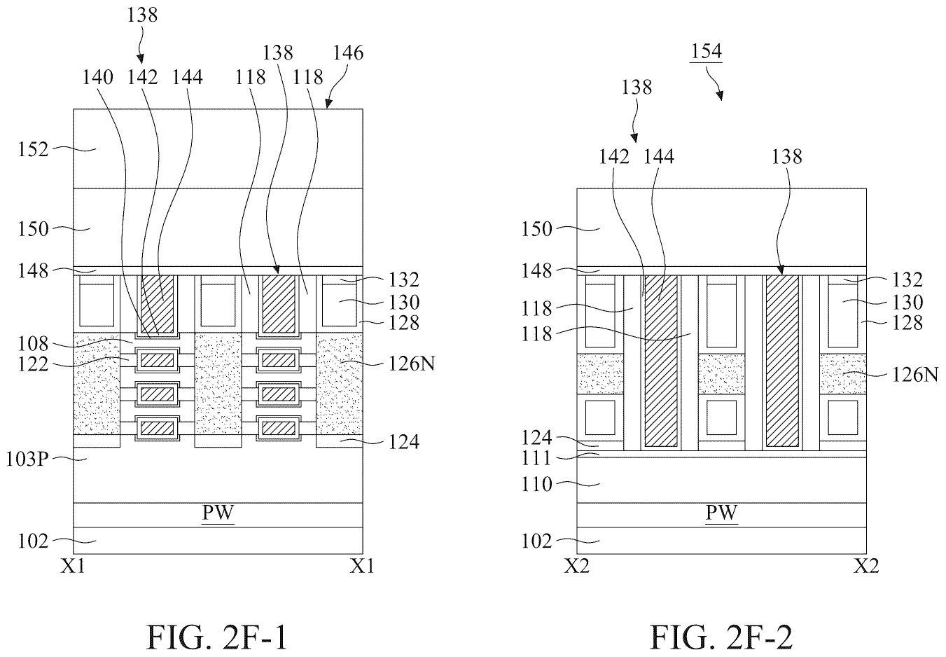

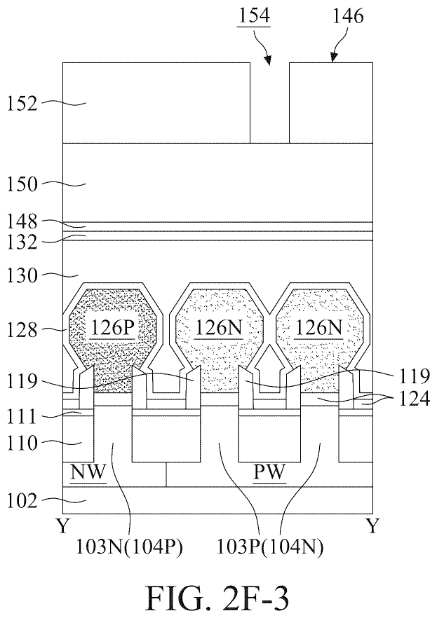

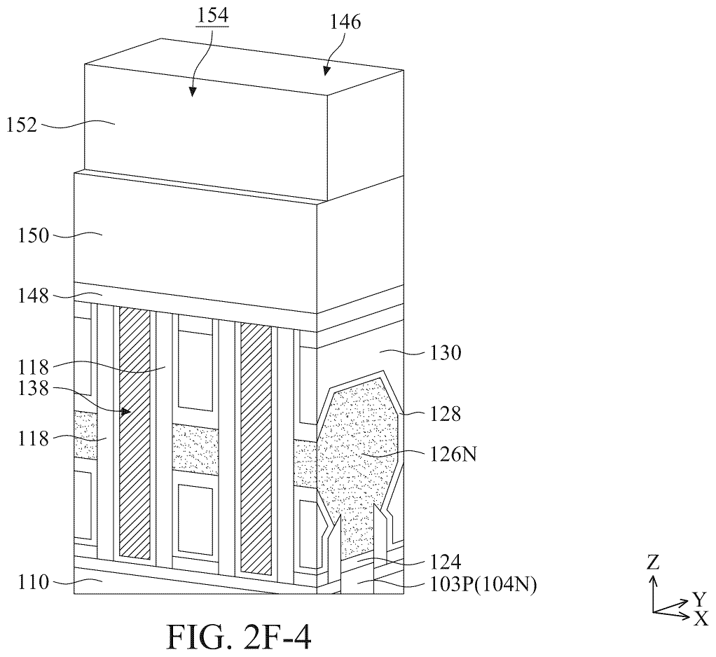

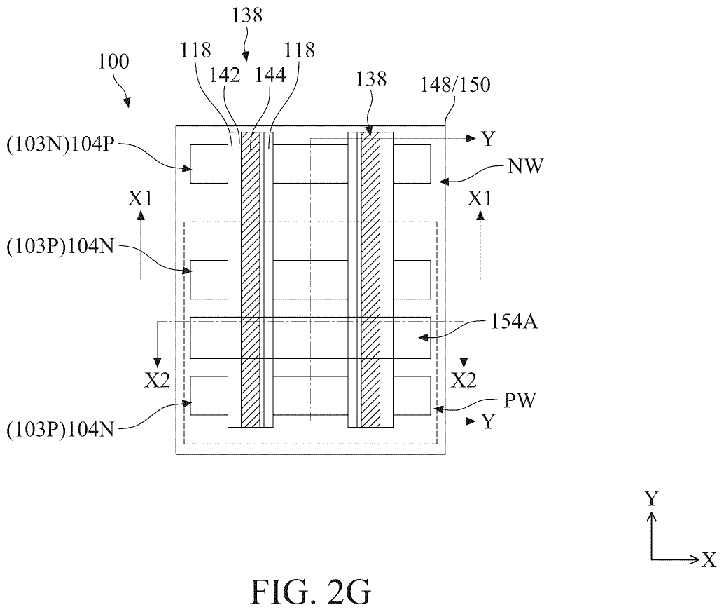

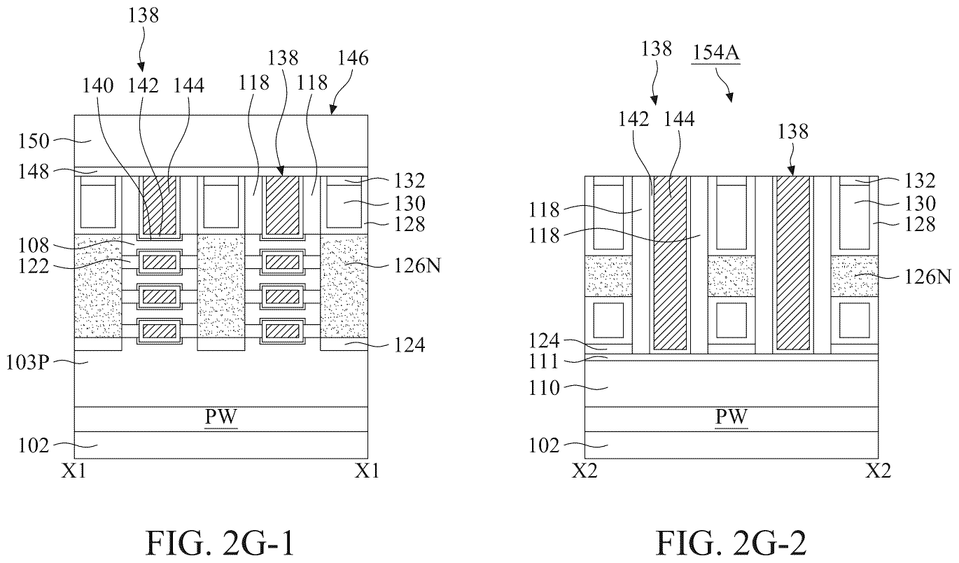

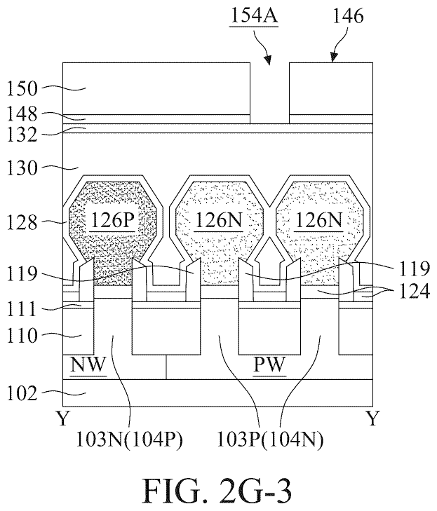

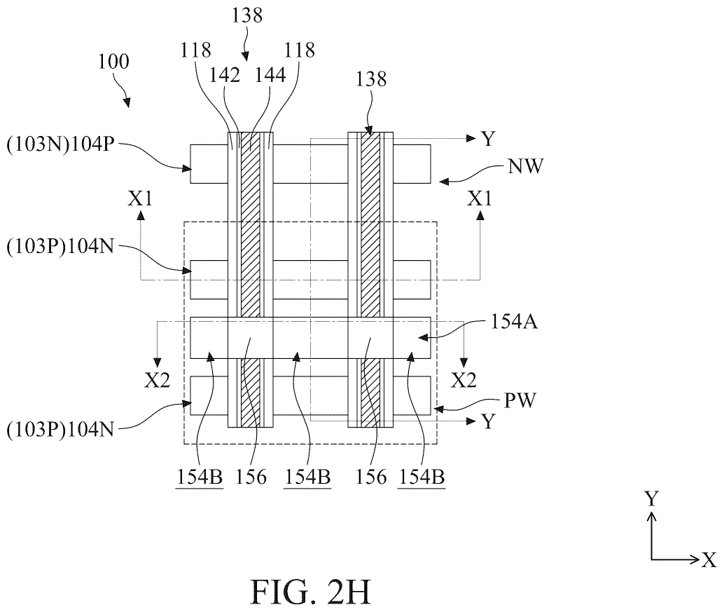

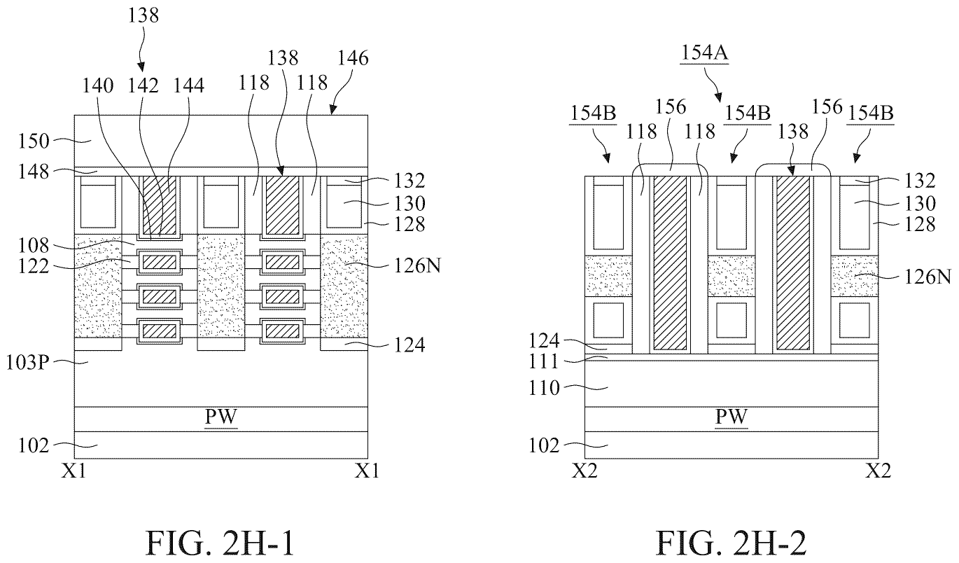

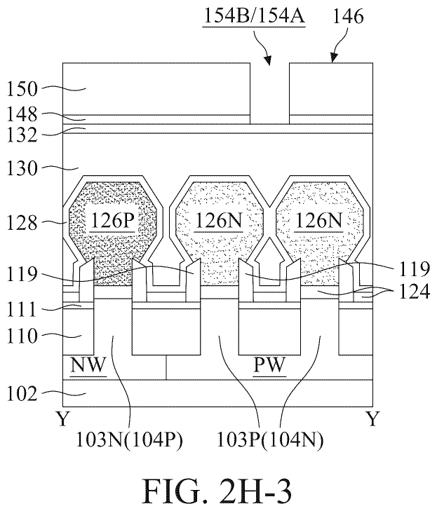

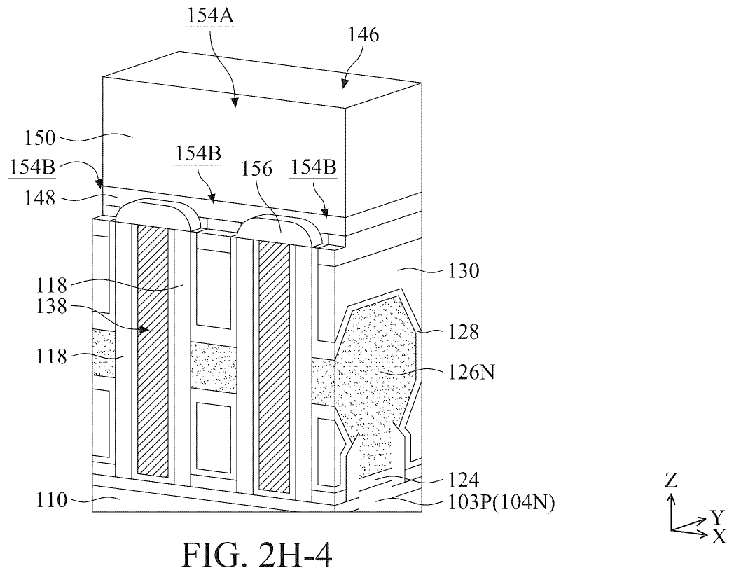

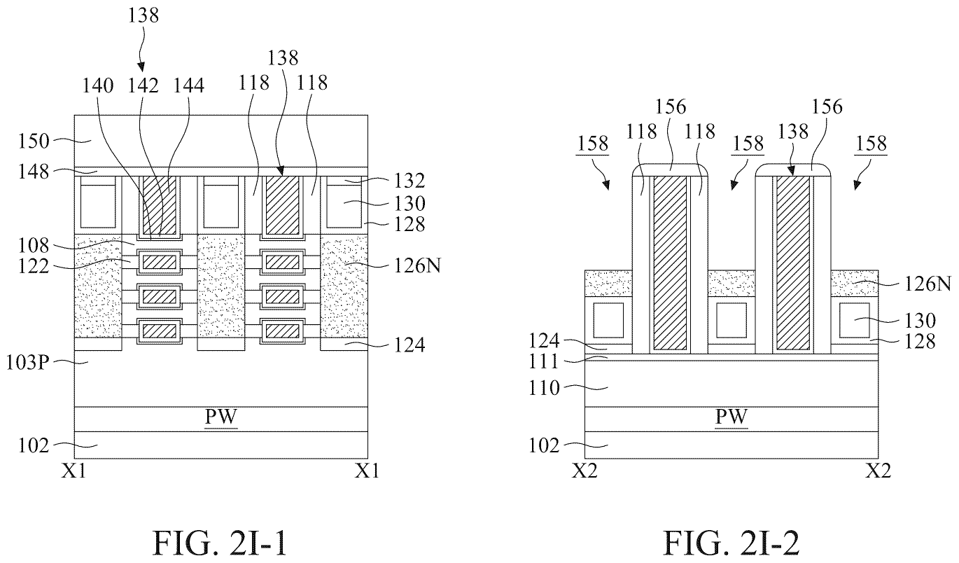

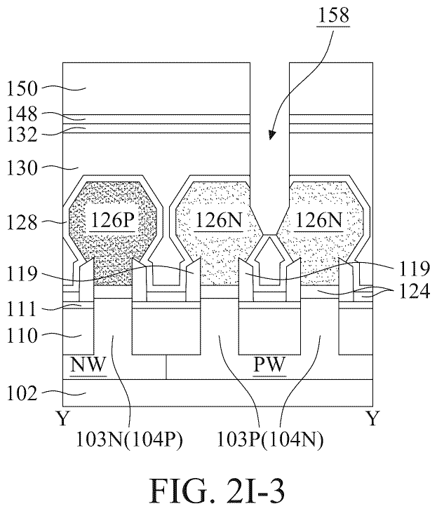

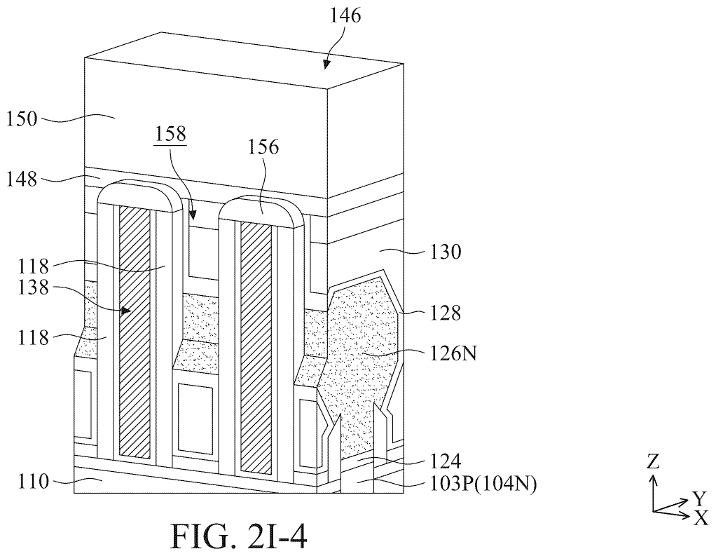

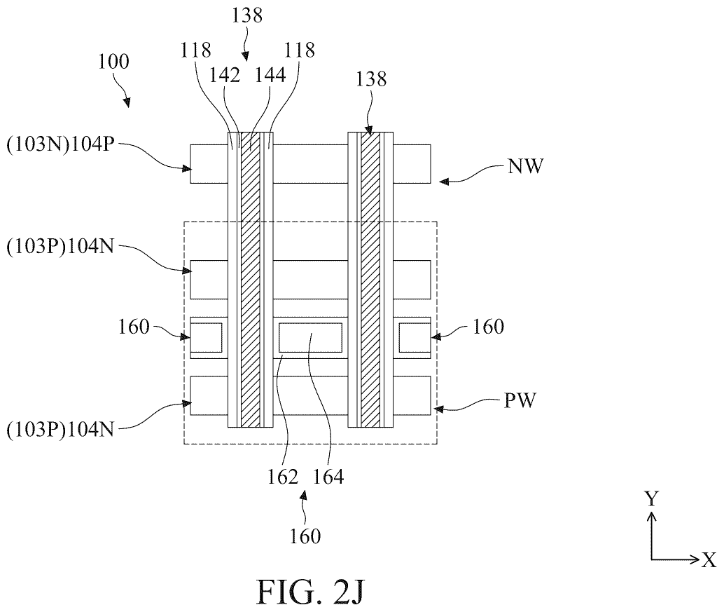

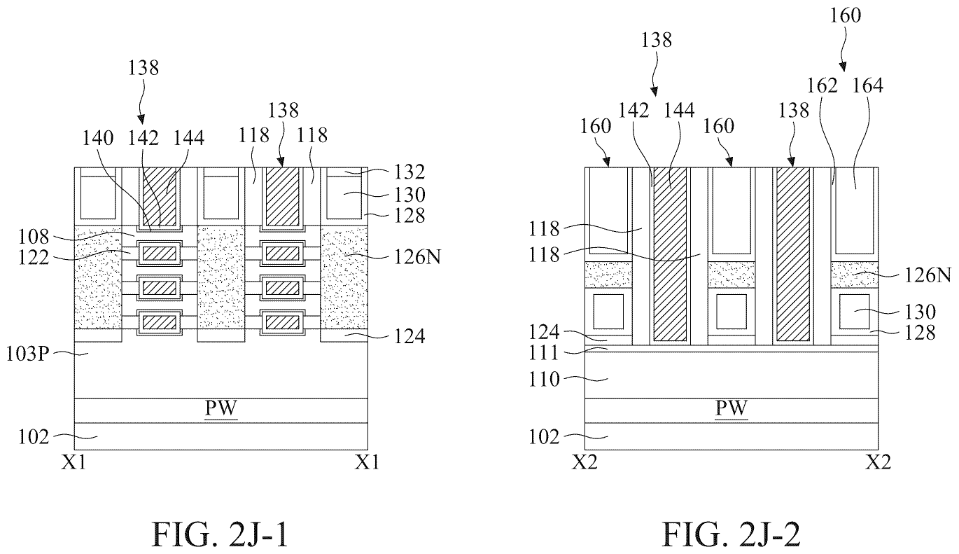

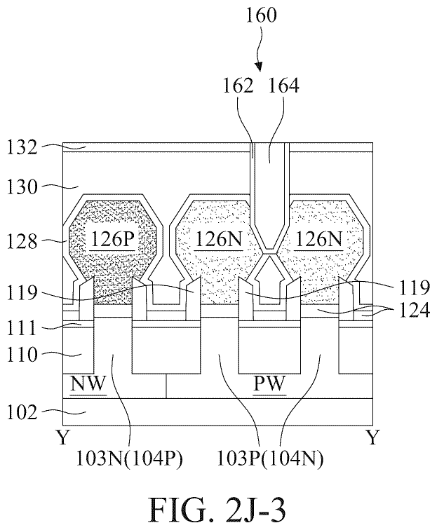

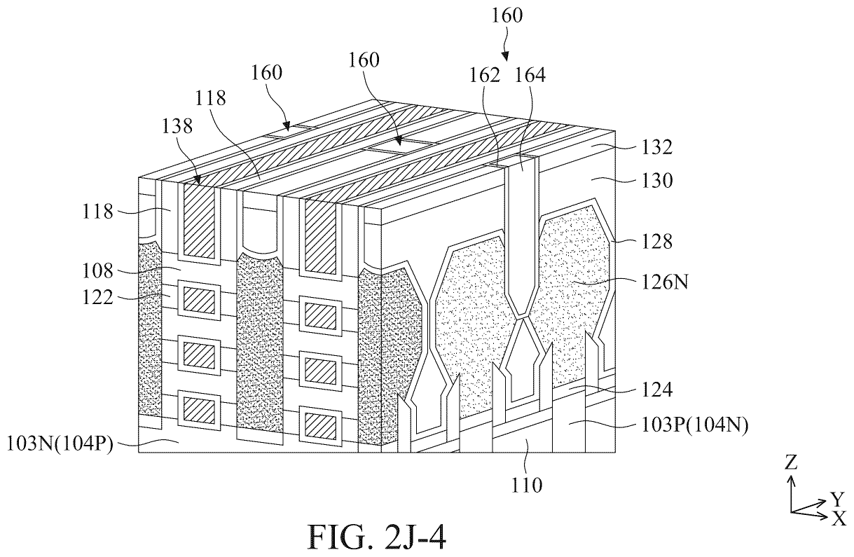

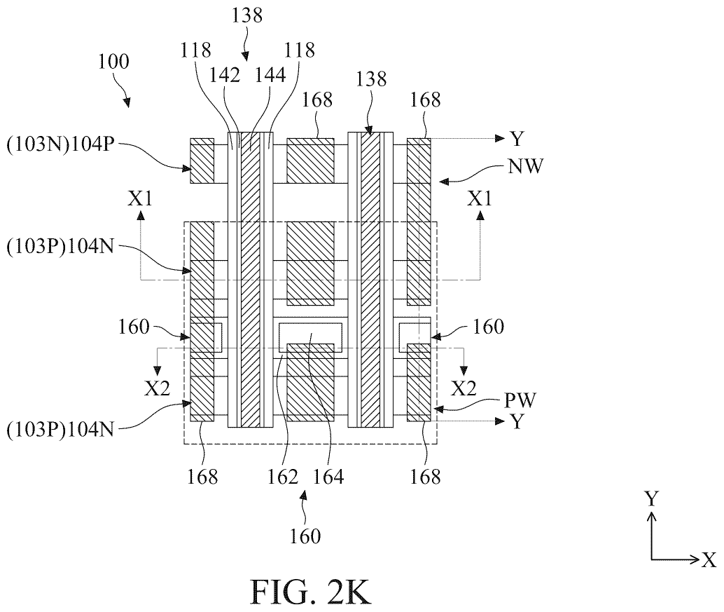

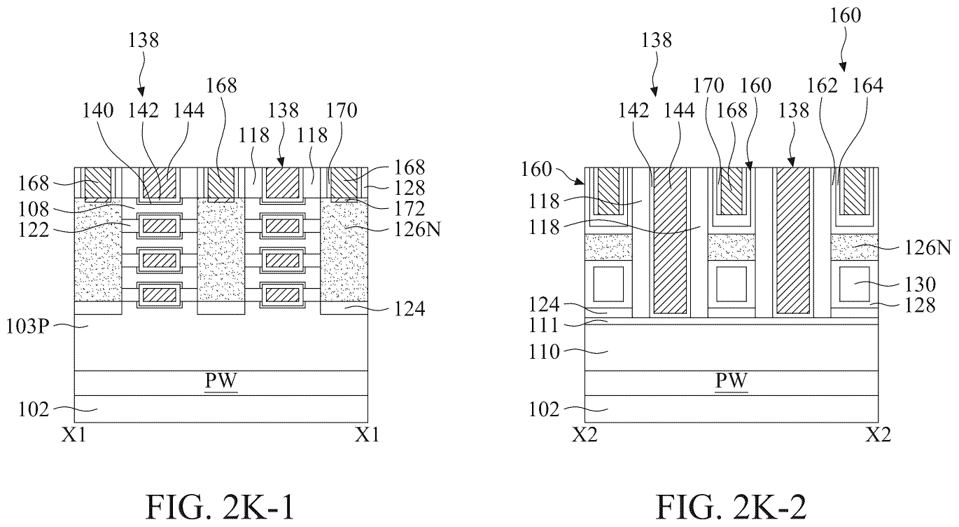

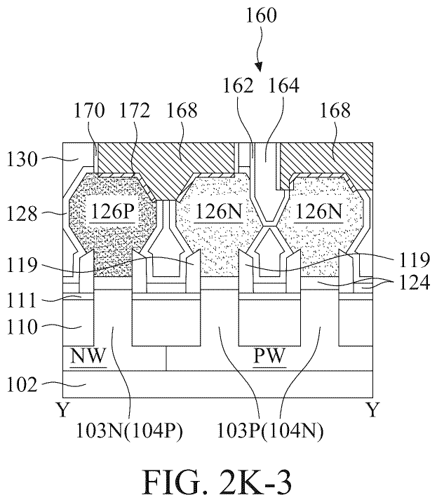

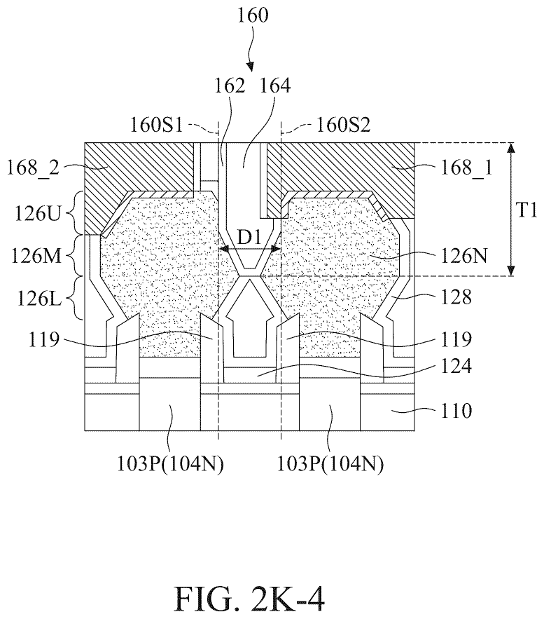

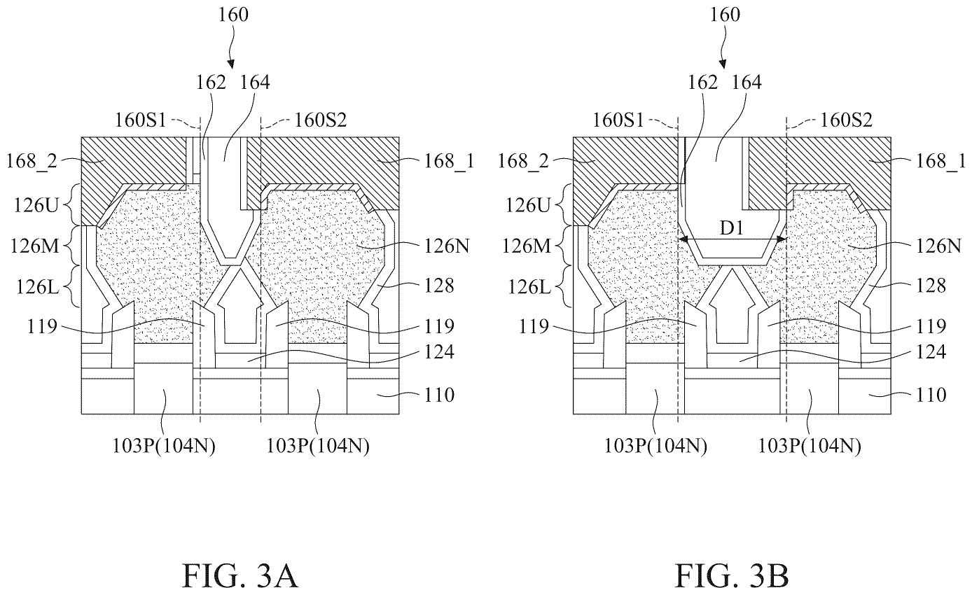

FIGS. 2A through 2K-3 are schematic views illustrating the formation of a semiconductor structure 100 at various intermediate stages, in accordance with some embodiments of the disclosure. FIGS. 2A, 2E, 2G, 2H, 2J and 2K are top views of the semiconductor structure 100, and illustrate reference cross-sections that are used in later figures. Cross-section X1-X1 is a plan parallel to the longitudinal axis (X direction) of active regions 104N and through an active region 104N. Cross-section X2-X2 is a plan parallel to the longitudinal axis (X direction) of active regions 104N and through between adjacent active regions 104N. Cross-section Y-Y is in a plane parallel to the longitudinal axis (Y direction) of a final gate stack 138 and across the source/drain regions of the active regions 104.

FIGS. 2A-1, 2B-1, 2C-1, 2D-1, 2E-1, 2F-1, 2G-1, 2H-1, 2I-1, 2J-1 and 2K-1 correspond to Cross-section X1-X1. FIGS. 2A-2, 2B-2, 2C-2, 2D-2, 2E-2, 2F-2, 2G-2, 2H-2, 2I-2, 2 J-2 and 2K-2 correspond to Cross-section X2-X2. FIGS. 2A-3, 2B-3, 2C-3, 2D-3, 2E-3, 2F-3, 2G-3, 2H-3, 2I-3, 2J-3 and 2K-3 correspond to Cross-section Y-Y. FIGS. 2C-4, 2F-4, 2H-4, 2I-4 and 2J-4 are perspective views of the semiconductor structure 100.

FIGS. 2A to 2A-3 illustrate a semiconductor structure 100 after the formation of active regions 104N and 104P, an isolation structure 110, a protection layer 111, dummy gate structures 112, gate spacer layers 118 and fin spacer layers 119, in accordance with some embodiments.

A substrate 102 is provided, as shown in FIGS. 2A-1 to 2A-3, in accordance with some embodiments. The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

An n-type well NW and a p-type well PW are formed in the substrate 102, in accordance with some embodiments. In some embodiments, the n-type well NW and the-p type well PW have different electrically conductive types. In some embodiments, the wells NW and PW are formed by respective ion implantation processes. In some embodiments, the ion implantation processes may be performed several times with different dosages and different energy intensities. In some embodiments, the ion implantation process may include anti-punch through (APT) implant.

Active regions 104 (including 104N and 104P) are formed over the substrate 102 as shown in FIGS. 2A to 2A-3, in accordance with some embodiments. In some embodiments, the active regions 104N and 104P extend in the X direction. In some embodiments, the active regions 104N and 104P are the fin structures 104N and 104P as shown in FIG. 1. The formation of the active regions 104N and 104P includes forming an epitaxial stack over the substrate 102 using an epitaxial growth process, in accordance with some embodiments. The epitaxial stack includes alternating first semiconductor layers 106 and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, and the second semiconductor layers 108 will form nanostructures (e.g., nanowires or nanosheets) that laterally extend between source/drain features and serve as the channel for the resulting semiconductor devices (such as nanostructure transistors), in accordance with some embodiments.

The formation of the active regions 104N and 104P further includes patterning the epitaxial stack and underlying wells PW and NW using photolithography and etching processes, thereby forming trenches, in accordance with some embodiments. The active regions 104N and 104P protrude from between trenches, in accordance with some embodiments.

The p-type well PW protruding from between the trenches forms the lower fin element 103P of the active region 104N, and the n-type well NW protruding from between the trenches forms the lower fin element 103N of the active region 104P, in accordance with some embodiments. The remainder of the epitaxial stack (including the semiconductor layers 106 and 108) forms the upper fin elements of the active regions 104N and 104P, in accordance with some embodiments. In some other embodiments, the wells NW and PW may be not formed.

In some embodiments, each of the second semiconductor layers 108 has a thickness in a range from about 3 nm to about 20 nm. In some embodiments, each of the first semiconductor layers 106 has a thickness in a range from about 3 nm to about 15 nm. The thickness of the second semiconductor layers 108 may be greater than, equal to, or less than the first semiconductor layers 106, depending on the amount of gate materials to be filled in spaces where the first semiconductor layers 106 are removed. Although three first semiconductor layers 106 and three second semiconductor layers 108 are shown, the number is not limited to three, and can be two or four, and is less than 10.

An isolation structure 110 is formed to surround the lower fin elements 103N and 103P, as shown in FIGS. 2A-2 and 2A-3, in accordance with some embodiments. The isolation structure 110 is configured to electrically isolate active regions 104 from one another, and is also referred to as shallow trench isolation (STI) feature, in accordance with some embodiments. In some embodiments, the isolation structure 110 has a substantially flat top surface. In some other embodiments, the isolation structure 110 has a curved top surface.

The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process (e.g., chemical mechanical polishing (CMP), etching back process, or a combination thereof) is performed on the insulating material, in accordance with some embodiments. The insulating material is then recessed by an etching process (such as dry plasma etching and/or wet chemical etching) until the upper fin elements of the active regions 104 are exposed, in accordance with some embodiments. The top portions of the lower fin elements 103N and 104P may be further exposed from the isolation structure 110, in accordance with some embodiments.

A protection layer 111 is optionally formed on the upper surface of the isolation structure 110, as shown in FIGS. 2A-2 and 2A-3, in accordance with some embodiments. The protection layer 111 is made of silicon-containing dielectric materials, such as silicon oxide (SiO2), silicon nitride (SiN), silicon oxynitride (SiON), silicon carbon nitride (SiCN), silicon oxycarbonitride (SiOCN), and/or oxygen-doped silicon carbonitride (Si(O)CN). The first protection layer 111 and the isolation structure 110 are made of different materials and have a great difference in etching selectivity. For example, the isolation structure 110 is made of silicon oxide (SiO), and the protection layer 111 is made of silicon nitride (SiN).

The formation of the protection layer 111 includes globally and conformally depositing a dielectric material over the semiconductor structure 100 using ALD, CVD (such as LPCVD, PECVD or HDP-CVD or a combination thereof, followed by an etching process, in accordance with some embodiments. The top portions of the lower fin element 103N and 104P may be further exposed from the protection layer 111, in accordance with some embodiments.

Dummy gate structures 112 are formed across the active regions 104N and 104P and the protection layer 111 (and the underlying isolation structure 110), as shown in FIGS. 2A, 2A-1 and 2A-2, in accordance with some embodiments. The dummy gate structures 112 are configured as sacrificial structures and will be replaced with the final gate stacks, in accordance with some embodiments. In some embodiments, the dummy gate structures 112 extend in the Y direction. The dummy gate structures 112 surround the channel regions of the active regions 104N and 104P, in accordance with some embodiments. The dummy gate structures 112 are the gate structures 112 shown in FIG. 1.

Each of the dummy gate structures 112 includes a dummy gate dielectric layer 114 and a dummy gate electrode layer 116 over the dummy gate dielectric layer 114, in accordance with some embodiments. In some embodiments, the dummy gate dielectric layer 114 is conformally formed along the upper fin elements of the active regions 104 using ALD, CVD, thermal oxidation, physical vapor deposition (PVD), another suitable technique, or a combination thereof. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTiO, HfAlO.

In some embodiments, the dummy gate electrode layer 116 is made of semiconductor material such as polysilicon or poly-silicon germanium. In some embodiments, the material for the dummy gate electrode layer 116 is deposited using CVD, ALD, another suitable technique, or a combination thereof. Once the material for the dummy gate electrode layer 116 is deposited, the material for the dummy gate electrode layer 116 is planarized, and the material for the dummy gate electrode layer 116 and the dielectric material are patterned into the dummy gate structures 112 using photolithography and etching processes.

Gate spacer layers 118 are formed along opposite sidewalls of the dummy gate structures 112, and fin spacer layers 119 are formed along opposite sidewalls of the active regions 104N and 104P, as shown in FIGS. 2A to 2A-3, in accordance with some embodiments. The gate spacer layers 118 extend in the Y direction and across the active regions 104N and 104P and the isolation structure 110, in accordance with some embodiments. The gate spacer layers 118 are used to offset the subsequently formed source/drain features and separate the source/drain features from the gate structure, in accordance with some embodiments. The fin spacer layers 119 extend in the X direction, in accordance with some embodiments.

In some embodiments, the gate spacer layers 118 and the fin spacer layers 119 are formed from one or more continuous dielectric material(s). For example, in some embodiments, the formation of the gate spacer layers 118 and the fin spacer layers 119 includes globally and conformally depositing a dielectric material over the semiconductor structure 100 using ALD, CVD (such as LPCVD, PECVD or HDP-CVD or a combination thereof, followed by an anisotropic etching process, in accordance with some embodiments.

In some embodiments, the dielectric material may be silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the gate spacer layers 118 may include air gaps and/or a porous version of the above-mentioned dielectric materials.

After the anisotropic etching process, the vertical portions of the dielectric material left remaining on the opposite sides of the dummy gate structures 112 form the gate spacer layers 118, while the vertical portions of the dielectric material left remaining on the opposite sides of the active regions 104N and 104P form the fin spacer layers 119, in accordance with some embodiments.

FIGS. 2B-1 to 2B-3 illustrate a semiconductor structure 100 after the formation of source/drain recess 120 and inner spacer layers 122, in accordance with some embodiments.

An etching process is performed to recess the source/drain regions of the active regions 104N and 104P, thereby forming source/drain recesses 120, as shown in FIGS. 2B-1 and 2B-3, in accordance with some embodiments. The etching process may be an anisotropic etching process such as dry plasma etching, an isotropic etching process such as dry chemical etching, remote plasma etching or wet chemical etching, and/or a combination thereof. The gate spacer layers 118 and the dummy gate structures 112 may serve as etch masks such that the source/drain recesses 120 are formed self-aligned on opposite sides of the dummy gate structures 112, in accordance with some embodiments.

In some embodiments, the bottom of the source/drain recess 120 may extend into the lower fin elements 103N and 103P. The fin spacer layers 119 are also recessed in the etching process, in accordance with some embodiments. In some other embodiments, the fin spacer layers 119 is removed in the etching process. In some embodiments, the protection layer 111 may prevent the isolation structure 110 from being recessed in the etching process.

An etching process is performed to laterally recess, from the source/drain recesses 120, the first semiconductor layers 106 of the active regions 104N and 104P, thereby forming notches, and then inner spacer layers 122 are formed in the notches, as shown in FIG. 2B-1, in accordance with some embodiments. The inner spacer layers 122 abut the recessed side surfaces of the first semiconductor layers 106, in accordance with some embodiments. The inner spacer layers 122 may avoid the source/drain features and the gate stack from being in direct contact and are configured to reduce the parasitic capacitance between the gate stack and the source/drain features (i.e., Cgs and Cgd), in accordance with some embodiments.

In some embodiments, the inner spacer layers 122 are made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. In some embodiments, the inner spacer layers 122 may include air gaps and/or a porous version of the above-mentioned dielectric materials. In some embodiments, the inner spacer layers 122 are made of a different material than the gate spacer layers 118.

In some embodiments, the inner spacer layers 122 are formed by depositing a dielectric material to fill the notches using ALD, CVD (such as PECVD, LPCVD or HARP), another suitable technique, or a combination thereof, and the dielectric material outside the notches are then etched away using an anisotropic etching process such as dry plasma etching, an isotropic etching process such as dry chemical etching, remote plasma etching or wet chemical etching, or a combination thereof.

FIGS. 2C-1 to 2C-4 illustrate a semiconductor structure 100 after the formation of interposing layers 124, source/drain features 126N and 126P, a contact etching stop layer 128 and an interlayer dielectric layer 130, and dielectric cap layer 132, in accordance with some embodiments.

Interposing layers 124 are formed on the lower fin elements 103N and 103P, as shown in FIGS. 2C-1 and 2C-4, in accordance with some embodiments. In some embodiments, the interposing layers 124 do not cover the sidewalls of the bottommost second semiconductor layers 108. In some embodiments, the interposing layers 124 are made of dielectric material silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the interposing layers 124 are formed by depositing a dielectric material over the semiconductor structure 100, followed by an etching-back processes. In some embodiments, semiconductor interposing layers (not shown) may be grown on the lower fin elements before the interposing layers 124 are formed.

In some embodiments, the interposing layers 124 are made of semiconductor material such as undoped silicon, and/or undoped silicon germanium. In some embodiments, the interposing layers 124 may include a semiconductor material on the lower fin elements 103N and 103P and a dielectric material on the semiconductor material.

Source/drain features 126N are grown from the exposed side surfaces of the second semiconductor layers 108 in the p-type well PW and source/drain features 126P are grown from the exposed side surfaces of the second semiconductor layers 108 in the n-type well NW using one or more epitaxial growth processes, as shown in FIG. 2C-1 to 2C-4, in accordance with some embodiments. The epitaxial growth processes may be MBE, MOCVD, or VPE, or another suitable technique.

The source/drain features 126N and 126P fill the source/drain recesses 120, in accordance with some embodiments. The source/drain features 126N abut the second semiconductor layers 108 of the active region 104N and the inner spacer layers 122, in accordance with some embodiments. Similarly, although not shown in FIGS. 2C-1 to 2C-3, the source/drain features 126P abut the second semiconductor layers 108 of the active region 104P and the inner spacer layers 122.

In some embodiments, the thickness (i.e., the dimension in the Z direction) of the source/drain features 126N and 126P is different from the width (i.e., the dimension in the Y direction) of the source/drain features 126N and 126P, as shown in FIGS. 2C-3 and 2C-4. In some embodiments, the width of the source/drain features 126N and 126P are greater than the width of the lower fin elements 103P and 103N such that portions of the source/drain features 126N and 126P overhang the fin spacer layers 119 and the isolation structure 110.

In some embodiments, the source/drain features 126N and 126P may grow to have a wider portion protruding from between the fin spacer layers 119. In some embodiments, the wider portion of the source/drain features 126N and 126P have facet surfaces that have specific crystalline orientations. Although the source/drain features 126N and 126P are illustrated as having facet surfaces, the wider portion of the source/drain features 126N and/or source/drain features 126P may have a curved surface in some other embodiments. In some embodiments, the source/drain features 126N are separate from each other. In some other embodiments, the source/drain features 126N may merge with each other at their widest portions.

In some embodiments, the source/drain features 126N and the source/drain features 126P may be formed separately. For example, a patterned mask layer (such as a photoresist layer and/or a hard mask layer) may be formed to cover the semiconductor structure 100 over the n-type well NW, and then the source/drain features 126N are grown. Afterward, the patterned mask layer may be removed. Similarly, a patterned mask layer (such as a photoresist layer and/or a hard mask layer) is formed to cover the semiconductor structure 100 over the p-type well PW, and then the source/drain features 126P are grown. Afterward, the patterned mask layer may be removed. In some embodiments, the source/drain features 126N and 126P are in-situ doped during the epitaxial processes.

In some embodiments, the source/drain features 126N are made of semiconductor epitaxial material such as SiP, SiAs, SiCP, SiC, Si, GaAs, another suitable semiconductor material, or a combination thereof. In some embodiments, the source/drain features 126N are doped with the n-type dopant during the epitaxial growth process. For example, the n-type dopant may be phosphorous (P) or arsenic (As). For example, the source/drain features 126N may be the epitaxially grown Si doped with phosphorous to form silicon: phosphor (Si:P) source/drain features and/or arsenic to form silicon: arsenic (Si:As) source/drain feature. In some embodiments, the concentration of the dopants (e.g., P) in the source/drain features 126N is in a range from about 2×10¹⁹/cm⁻³ to about 3×10²¹/cm⁻³.

The source/drain features 126P are made of semiconductor material such as SiGe, Si, GaAs, another suitable semiconductor material, or a combination thereof. In some embodiments, the source/drain features 126P are doped with the p-type dopant during the epitaxial growth process. For example, the p-type dopant may be boron (B) or BF2. For example, the source/drain features 126P may be the epitaxially grown SiGe doped with boron (B) to form silicon germanium: boron (SiGe: B) source/drain feature. In some embodiments, the concentration of the dopants (e.g., B) in the source/drain features 126P is in a range from about 1×10¹⁹/cm⁻³ to about 6×10²⁰/cm⁻³.

A contact etching stop layer 128 is formed over the semiconductor structure 100 to cover the source/drain features 126N and 126P, as shown in FIGS. 2C-2 and 2C-3, in accordance with some embodiments. In some embodiments, the contact etching stop layer 128 is made of a dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material.

In some embodiments, the contact etching stop layer 128 is globally and conformally deposited using ALD, CVD (such as LPCVD, PECVD, HDP-CVD and HARP), another suitable method, and/or a combination thereof. In some embodiments, the dielectric constant of the contact etching stop layer 128 is greater than the dielectric constant of the inner spacer layers 122 and the dielectric constant of the gate spacer layers 118.

In some embodiments, portions of the contact etching stop layer 128 formed on the overhangs of the adjacent two source/drain features 126P are connected with each other, as shown in FIG. 2C-3. In some other embodiments, portions of the contact etching stop layer 128 formed on the overhangs of the adjacent two source/drain features 126P may be separate with each other.

An interlayer dielectric layer 130 is formed over the contact etching stop layer 128, as shown in FIGS. 2C-1 to 2C-4, in accordance with some embodiments. The interlayer dielectric layer 130 overfills the space between dummy gate structures 112, in accordance with some embodiments. In some embodiments, the interlayer dielectric layer 130 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material.

In some embodiments, the dielectric constant of the contact etching stop layer 128 is greater than the dielectric constant of the interlayer dielectric layer 130. In some embodiments, the thickness of the portion of the contact etching stop layer 128 along the gate spacer layer 128 and the source/drain features 126N and 126P is less than the thickness (i.e., dimension in the Z direction) and the width (i.e., dimension in the X and Y directions) of the interlayer dielectric layer 130.

In some embodiments, the dielectric material for the interlayer dielectric layer 130 is deposited using such as CVD (such as HDP-CVD, PECVD, HARP or FCVD), another suitable technique, or a combination thereof. The dielectric materials for the contact etching stop layer 128 and the interlayer dielectric layer 130 above the top surface of the dummy gate electrode layer 116 are removed using such as CMP, in accordance with some embodiments.

Afterward, the interlayer dielectric layer 130 is recessed to form trenches (not shown), and a dielectric cap layer 132 is formed to fill the trenches, as shown in FIG. 3C-1 and 3C-4. The dielectric cap layer 132 is configured to protect the interlayer dielectric layer 130 in the following etching processes, and may have a different etching selectivity than the interlayer dielectric layer 130, in accordance with some embodiments. In some embodiments, the dielectric cap layer 132 is made of the same material as the contact etching stop layer 128.

In some embodiments, the dielectric cap layer 132 is made of a dielectric material, such as silicon nitride (SiN), silicon oxynitride (SiON), silicon oxide (SiO₂), oxygen-doped silicon carbide (SiC:O), oxygen-doped silicon carbonitride (Si(O)CN), silicon carbide (SiC), or another suitable dielectric material. In some embodiments, the formation of the dielectric cap layer 132 includes a deposition process, followed by a removal process (e.g., etching-back or CMP process).

FIGS. 2D-1 to 2D-3 illustrate a semiconductor structure 100 after the formation of gate trenches 134 and gaps 136, in accordance with some embodiments.

One or more etching processes are performed to remove the dummy gate structure 112 to form gate trenches 134 and remove the first semiconductor layers 106 of the active regions 104N and 104P to form gaps 136, as shown in FIGS. 2D-1, 2D-2 and 2D-3, in accordance with some embodiments. In some embodiments, the gate trenches 134 expose the channel regions of the active regions 104N and 104P. In some embodiments, the gate trenches 134 further expose the sidewalls of the gate spacer layers 118 facing the channel region. In some embodiments, the gaps 136 expose the sidewalls of the inner spacer layers 122 facing the channel region. The one or more etching processes may include an anisotropic etching process such as dry plasma etching, an isotropic etching process such as dry chemical etching, remote plasma etching or wet chemical etching, or a combination thereof. In some embodiments, the protection layer 111 may prevent the isolation structure 110 from being recessed in the etching process.

After the one or more etching processes, the four main surfaces of the second semiconductor layers 108 are exposed, in accordance with some embodiments. The exposed second semiconductor layers 108 of the active region 104N and 104P form nanostructures 108, in accordance with some embodiments. As the term is used herein, “nanostructures” refers to the semiconductor layers with cylindrical shape, bar shaped and/or sheet shape. A corner-rounding process is optionally performed to shape the profile the nanostructures 108, in accordance with some embodiments. As a result, each of the nanostructures 108 may have a dumbbell shape in the cross-section that is along and through the active region, as shown in FIG. 2D-1.

FIGS. 2E-1 to 2E-3 illustrate a semiconductor structure 100 after the formation of final gate stacks 138.

Final gate stacks 138 are formed in the gate trenches 134 and gaps 136, and they are thereby wrapped around the nanostructures 108, as shown in FIGS. 2E to 2E-2, in accordance with some embodiments. In some embodiments, the final gate stacks 138 extend in the Y direction. The final gate stacks 138 engage the channel region so that current can flow between the source/drain regions during operation. In some embodiments, each of the final gate stacks 138 includes an interfacial layer 140, a gate dielectric layer 142 and a metal gate electrode layer 144, as shown in FIGS. 2E to 2E-2, in accordance with some embodiments.

The interfacial layer 140 is formed on the exposed surfaces of the nanostructures 108 and the exposed surfaces of the lower fin elements 103N and 103P, in accordance with some embodiments. The interfacial layer 140 wraps around the nanostructures 108, in accordance with some embodiments. In some embodiments, the interfacial layer 140 is made of a chemically formed silicon oxide. In some embodiments, the interfacial layer 140 is nitrogen-doped silicon oxide. In some embodiments, the interfacial layer 140 is formed using one or more cleaning processes. Said cleaning processes may include the use of ozone (O3), ammonia hydroxide-hydrogen peroxide-water mixture, hydrochloric acid-hydrogen peroxide-water mixture, or a combination thereof. Semiconductor material from the nanostructures 108 and the lower fin elements 103N and 103P is oxidized to form the interfacial layer 140, in accordance with some embodiments.

The gate dielectric layer 142 is formed conformally along the interfacial layer 140 to wrap around the nanostructures 108, in accordance with some embodiments. The gate dielectric layer 142 is further formed along the exposed sidewalls of the gate spacer layers 118 and the inner spacer layers 122 facing the channel region, in accordance with some embodiments. The gate dielectric layer 142 may be a high-k dielectric layer. In some embodiments, the high-k dielectric layer is dielectric material with a high dielectric constant (k value), for example, greater than 9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba, Sr)TiO₃ (BST), Si₃N₄, oxynitrides (SiON), a combination thereof, or another suitable material. The high-k dielectric layer may be deposited using ALD, PVD, CVD, or another suitable technique. In some embodiments, the dielectric constant of the gate dielectric layer 142 is higher than the dielectric constant of the gate spacer layer 118. In some embodiments, the dielectric constant of the gate dielectric layer 142 is at least twice the dielectric constant of the interlayer dielectric layer 130.

The metal gate electrode layer 144 is formed over the gate dielectric layer 142 and overfills the remainder of the gate trenches 134 and the gaps 136, in accordance with some embodiments. In some embodiments, the metal gate electrode layer 144 is made of more than one conductive material, such as a metal, metal alloy, conductive metal oxide, metal nitride, another suitable conductive material, or a combination thereof. For example, the metal gate electrode layer 144 may be made of Ti, Ag, Al, TiAlN, TaC, TaCN, TaSiN, Mn, Zr, TiN, TaN, Ru, Mo, WN, Cu, W, Re, Ir, Co, Ni, Pt, another suitable conductive material, or multilayers thereof. The metal gate electrode layer 144 may be a multi-layer structure with various combinations of a diffusion barrier layer, work function layers with a selected work function to enhance the device performance for n-channel FETs or p-channel FETs, a capping layer to prevent oxidation of work function layers, a glue layer, and a metal fill layer to reduce the total resistance of gate stacks, or another suitable layer.

A planarization process such as CMP may be performed on the semiconductor structure 100 to remove the materials of the gate dielectric layer 142 and the metal gate electrode layer 144 formed above the upper surface of the dielectric cap layer 132, in accordance with some embodiments. The final gate stacks 138 that are wrapped around the nanostructures 108 combine with the neighboring source/drain features 126N or 126P to form nanostructure transistors. In some embodiments, the transistors formed in the p-type well PW are the n-channel nanostructure transistor, and the transistors formed in the n-type well NW are the p-channel nanostructure transistor.

FIGS. 2F-1 to 2F-4 illustrate a semiconductor structure 100 after the formation of a patterned mask layer 146.

A patterned mask layer 146 is formed over the semiconductor structure 100, as shown in FIGS. 2F-1 to 2F-4, in accordance with some embodiments. The patterned mask layer 146 may be a tri-layer mask structure which includes a bottom hard mask layer 148, a middle hard mask layer 150, and a top photoresist mask 152, in accordance with some embodiments. The top photoresist mask 152 of the patterned mask layer 140 has a trench pattern 154 which is located directly above the isolation structure 110 in the p-type well PW, in accordance with some embodiments. The trench pattern 154 extends lengthwise along the X direction across gate stacks 138, in accordance with some embodiments.

In some embodiments, the bottom hard mask layer 148 may be a bottom anti-reflective coating (BARC) layer such as an inorganic material or an organic material (e.g., polymer, oligomer, or monomer). In some embodiments, the bottom hard mask layer 148 is made of organic material including carbon and oxygen, which is made of cross-linked photo-sensitive material. In some embodiments, the bottom hard mask layer 148 is formed by spin-on coating process, a CVD process (such as LPCVD, PECVD, HDP-CVD, HARP or FCVD), another suitable method, or a combination thereof.

In some embodiments, the middle hard mask layer 150 is made of silicon oxide-based material, oxide of metal such as zinc oxide (ZnO), aluminum oxide (Al₂O₃), tin oxide (SnO), lead oxide (PbO), beryllium oxide (BeO), chromium oxide (CrO, Cr₂O₃, Cr₂O₃ or Cr₃O₄), and/or another suitable material. The top photoresist mask 152 is formed by a photolithography process, in accordance with some embodiments. The photolithography process can include forming a photoresist layer, for example, by spin coating, performing a pre-exposure baking process, performing an exposure process using a mask (or a reticle), performing a post-exposure baking process, and performing a developing process. During the exposure process, the photoresist layer is exposed to radiation energy, where the mask blocks, transmits, and/or reflects radiation to the photoresist layer depending on a mask pattern of the mask and/or mask type, such that an image is projected onto the photoresist layer that corresponds with the mask pattern. Since the photoresist layer is sensitive to radiation energy, exposed portions of the resist layer chemically change, and exposed (or non-exposed) portions of the resist layer are dissolved during the developing process depending on the characteristics of the resist layer and characteristics of a developing solution used in the developing process. After development, the patterned photoresist layer forms the top photoresist mask 152 which includes the trench pattern 154 that corresponds with the mask.

FIGS. 2G to 2G-3 illustrate a semiconductor structure 100 after an etching process.

An etching process is performed on the patterned mask layer 146 to transfer the trench pattern 154 into the bottom hard mask layer 148 and the middle hard mask layer 150 of the patterned mask layer 146, as shown in FIG. 2G to 2G-3, in accordance with some embodiments. The extended trench pattern 154 are denoted as 154A. The etching process may be anisotropic etching process such as dry plasma etching. After the etching process, the final gate stacks 138, the gate spacer layers 118 and the dielectric cap layer 132 are exposed from the trench pattern 154A, as shown in FIG. 2G-2, in accordance with some embodiments. The top photoresist mask 152 is removed in the etching process, or by an additional process (e.g., ashing, etching or wet strip process).

FIGS. 2H to 2H-4 illustrate a semiconductor structure 100 after the formation of protection features 156.

Protection features 156 are selectively formed in the trench pattern 154A on the top surface of the portion of the final gate stacks 138 that is exposed from the trench pattern 154A, as shown in FIGS. 2H, 2H-2 and 2H-4, in accordance with some embodiments. The protection features 156 further cover part or all the top surface of the portion of the gate spacer layers 118 exposed from the trench pattern 154A, in accordance with some embodiments. In some embodiments, the top surface of the dielectric cap layer 132 remains exposed from the trench pattern 154A.

The protection features 156 are configured to the protect the final gate stack 138 and the gate spacer layers 118 in the subsequent etching process, in accordance with some embodiments. The patterned middle hard mask layer 150, the patterned bottom hard mask layer 148 and the protection features 156 together serve as a patterned mask layer in the subsequent etching process, in accordance with some embodiments. The trench pattern 154A is divided into several opening patterns 154B by the protection features 156, in accordance with some embodiments. The opening patterns 154B may be also referred to as cut source/drain epitaxy (Cut-EPI) patterns.

In some embodiments, the protection features 156 are made of metal (e.g., cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), or another suitable metal material) or metal oxide (e.g., zinc oxide (ZnO), aluminum oxide (Al₂O₃), tin oxide (SnO), lead oxide (PbO), beryllium oxide (BeO), or chromium oxide (CrO)).

The protection features 156 may be formed using the self-assembled monolayer (SAM) technique. In some embodiments, a self-assembled monolayer is selectively formed on the metal surface (e.g., the exposed surface of the gate electrode layer 144), and the protection features 156 are then selectively deposited on self-assembled monolayer, and extend to cover the top surface of the gate spacer layers 118.

The self-assembled monolayer may be made of amphiphilic organic molecules, in which one end of the molecule, a head group (anchor) shows a specific affinity for a metal surface. The head group may be connected (e.g., bonded) to an alkyl chain in which a tail (terminal end) can be functionalized, for example, to vary wetting and interfacial properties, in accordance with some embodiments. In some embodiments, the tail is functionalized to enhance deposition selectivity of the deposition process of the protection features 156. For example, the tail may be hydrophobic so that precursors of the deposition process may not adhere or be anchored to the self-assembled monolayer.

In some other embodiments, a self-assembled monolayer is selectively formed on the dielectric surface (e.g., the expose surface of the dielectric cap layer 132), and the protection features 156 are then deposited on the expose surface of the metal gate electrode layer 144 but substantially not formed over the self-assembled monolayer.

FIGS. 2I-1 to 2I-4 illustrate a semiconductor structure 100 after an etching process.

An etching process is performed on the semiconductor structure 100 using the patterned middle hard mask layer 150, the patterned bottom hard mask layer 148 and the protection features 156, thereby forming cut openings 158, as shown in FIGS. 2I-2 and 2I-3, in accordance with some embodiments. The etching process may be anisotropic etching process such as dry plasma etching. The etching process removes the portion of the dielectric cap layer 132, the interlayer dielectric layer 130 and the contact etching stop layer 128 and the source/drain features 126N underlying the opening patterns 154B, in accordance with some embodiments. In some embodiments, the portions of the final gate stacks 138 and the gate spacer layers 118 covered by the protection features 156 remain unetched.

In some embodiments, the bottom of the cut openings 158 are located within the interlayer dielectric layer 130. In some other embodiments, the bottom of the cut openings 158 extend to the interposing layers 124, or alternatively extend to the protection layer 111, or yet alternatively extend to the isolation structure 110. In some embodiments where the source/drain features 126N merge with each other, the cut openings 158 cut through the merged source/drain feature into two separate source/drain features 126N.

FIGS. 2J to 2J-4 illustrate a semiconductor structure 100 after the formation of isolation features 160.

Isolation features 160 are formed in the cut opening 158, as shown in FIGS. 2J, 2J-2, 2J-3 and 2J-4, in accordance with some embodiments. The isolation features 160 are configured to prevent the adjacent source/drain features from being physically and electrically connected to each other, in accordance with some embodiments. Although the isolation features 160 are formed within the p-type well PW, the embodiments are not limited thereto. The isolation features 160 may be further formed within the n-type well NW and/or on the boundary between the n-type well NW and the p-type well PW in some embodiments.

The formation of the isolation features 160 includes conformally depositing a dielectric liner 162 along the semiconductor structure 100 to partially fill the cut openings 158, depositing a dielectric bulk layer 164 on the dielectric liner 162 to overfill the cut opening 158, and planarizing the dielectric liner 162 and the dielectric bulk layer 164, in accordance with some embodiments.

The dielectric liner 162 and the dielectric bulk layer 164 are made of dielectric material, such as silicon nitride (SiN), silicon oxynitride (SiON), silicon oxide (SiO₂), oxygen-doped silicon carbide (SiC:O), silicon carbonitride (SiCN), oxygen-doped silicon carbonitride (Si(O)CN), silicon carbide (SiC), or another suitable dielectric material. In some embodiments, the dielectric liner 162 and the dielectric bulk layer 164 are made of different materials and have different dielectric constant values. For example, the dielectric liner 162 is made of SiN, and the dielectric bulk layer 164 is made of SiO. In some embodiments, the dielectric liner 162 has a higher dielectric constant than the dielectric bulk layer 164. In some other embodiments, the isolation features 160 is made of a single dielectric material.

The deposition processes may be ALD, CVD (such as LPCVD, PECVD or HDP-CVD or a combination thereof, in accordance with some embodiments. The planarization process may be CMP or an etching-back process, in accordance with some embodiments. The planarization process is performed until the upper surface of the gate electrode layer 144 is exposed, in accordance with some embodiments.

FIGS. 2K to 2K-3 illustrate a semiconductor structure 100 after the formation of contact structures 168.

Contact structures 168 are formed through the isolation features 160, the interlayer dielectric layer 130 and the contact etching stop layer 128 to land on the source/drain features 126N and 126P, as shown in FIGS. 2K to 2K-3, in accordance with some embodiments. The contact structures 168 are located between the final gate stacks 138 and extend across source/drain regions of the active regions 104N and 104P, in accordance with some embodiments. The contact plugs 168 are electrically connected to the source/drain features 126N and 126P, in accordance with some embodiments.

In some embodiments, the formation of the contact structures 168 includes patterning the isolation features 160, the interlayer dielectric layer 130 and the contact etching stop layer 128 and the underlying source/drain features 126N and 126 to form contact openings (where the contact structures 168 are to be formed) using photolithography and etching processes. The etch process may include dry etching such as RIE, NBE, ICP etch, CPP etch, another suitable method, or a combination thereof.

Contact liners 170 are formed in the contact openings, in accordance with some embodiments. The contact liners 170 extend along the sidewalls of the contact openings and partially fill the contact openings, in accordance with some embodiments. In some embodiments, the contact liners 170 are made of dielectric material such as silicon nitride (SiN), silicon oxynitride (SiON), silicon carbon nitride (SiCN), silicon oxycarbonitride (SiOCN), and/or oxygen-doped silicon carbonitride (Si(O)CN), or a combination thereof. In some embodiments, the formation of the contact liners 170 includes depositing the dielectric material using ALD, CVD (such as LPCVD, PECVD or HDP-CVD), another suitable method, and/or a combination thereof, and followed by an etching-back process. The top surfaces of the source/drain features 126N and 126P are exposed from the contact openings again, in accordance with some embodiments.

Silicide layers 172 are formed on the exposed surfaces of the source/drain features 126N and 126P. In some embodiments, the silicide layers 172 formed on the n-type source/drain features 126N are made of WSi, NiSi, TiSi and/or CoSi. In some embodiments, the silicide layers 172 formed on the p-type source/drain features 126P are made of WSiGe, NiSiGe, TiSiGe and/or CoSiGe. In some embodiments, the formation of the silicide layers 172 includes depositing a metal material followed by one or more annealing processes. The semiconductive material (e.g., Si or SiGe) from the source/drain features 126N and 126P reacts with the metal material to form the silicide layers 172, in accordance with some embodiments. The unreacted metal material is then removed using a cleaning process.

The contact structures 168 may have a multilayer structure. One or more conductive materials are deposited on the silicide layers 172 to overfill the contact openings, in accordance with some embodiments. For example, one or more conductive materials include a barrier/adhesive layer and a metal bulk layer on the barrier/adhesive layer. In some embodiments, the barrier/adhesive layer is formed along the sidewalls and the bottom surface of the contact openings, and the metal bulk layer fills the remainders of the contact openings and is surrounded by the contact openings.

In some embodiments, the barrier/adhesive layer may be made of tantalum (Ta), tantalum nitride (TaN), titanium (Ti), titanium nitride (TiN), cobalt tungsten (CoW), another suitable material, or a combination thereof. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

In some embodiments, one or more conductive materials are deposited using CVD, PVD, e-beam evaporation, ALD, electroplating (ECP), electroless deposition (ELD), another suitable method, or a combination thereof to overfill the contact openings. In some embodiments, the metal bulk layer is formed using a selective deposition technique such as cyclic CVD process or ELD process, and it is not necessary to form the barrier/adhesive layer before depositing the metal bulk material.

The one or more conductive materials over the upper surface of the final gate stacks 138 are planarized using, for example, CMP. The top surfaces of the final gate stacks 138, the top surfaces of the gate spacer layers 118, the top surfaces of the contact structures 168, and the top surfaces of the isolation features 160 and substantially leveled, in accordance with some embodiments. In some embodiments, the dielectric cap layer 132 is removed in the planarization process.

FIG. 2K-4 is an enlarged view of FIG. 2K-3, in accordance with some embodiments. In some embodiments, the isolation feature 160 is equidistant to the adjacent active regions 104N and 104N. In some embodiments, the isolation feature 160 may be toward one of the adjacent active regions 104N and 104N. The dimension D1 of the isolation feature 160 in the Y direction is less than the spacing between adjacent active regions 104N, in accordance with some embodiments.

In some embodiments, the dimension D1 ranges from about 10 nm to about 30 nm. In some embodiments, the thickness T1 of the isolation feature 160 ranges from about 30 nm to about 100 nm. The dielectric layer 162 of the isolation feature 160 has a thickness about 1 nm to about 5 nm.

In the cross-section view across the source/drain regions of the active regions, the extension lines 160S1 and 160S2 of the opposite sidewalls (or edges) of the isolation feature 160 penetrate through the fin spacer layers 119, as shown in FIG. 2K-4, in accordance with some embodiments.

In some embodiments, each of the source/drain features 126N/126P includes a wider portion protruding from between the fin spacer layers 119, and the wider portion has a middle portion 126M which is the portion the source/drain feature 126N/126P having the greatest width (i.e., the dimension in the Y direction). In some embodiments, the wider portion has an upper portion 126U tapering upwardly from the middle portion 126M and a lower portion 126L tapering downwardly from the middle portion 126M. In some embodiments, the isolation feature 160 includes a bottom portion that tapers toward its bottom.

The isolation feature 160 partially perpetrates through the upper portion 126U and the middle portions 126M of the source/drain features 126N, in accordance with some embodiments. The isolation feature 160 extends to a portion of the contact etching stop layer 128 between the lower portions 126L of the source/drain features 126N. The isolation feature 160 abuts the of upper portion 126U the source/drain features 126N, and the isolation feature 160 partially overlaps with the middle portions 126M and the lower portions 126L of the source/drain features 126N. In some embodiments, the volume of the source/drain feature 126N which is cut by the isolation feature 160 is less than the volume of the source/drain feature 126P which is not cut by the isolation feature 160. In some embodiments, the surface of the source/drain features 126N interfaced with the isolation features 160 may have a different roughness from (e.g., higher than) the surface of the source/drain features 126N interfaced with the isolation features 160 interfaced with the contact etching stop layer 128 due to the etching process for forming the isolation features 160.

In some embodiments, the contact structure 168_1 partially perpetrates through the isolation feature 160 so as to abut the isolation feature 160 at the edge 160S2. The bottom surface of the contact structure 168_1 is higher than the bottom surface of the isolation feature 160, and a portion of the isolation feature 160 is located directly under the contact structure 168_1, in accordance with some embodiments. In some embodiments, the contact structure 168_2 is separated from the isolation feature 160 by the interlayer dielectric layer 130.

As the scale of the semiconductor devices continues to shrink, the spacing between the active regions 104 (i.e., the dimension of the isolation structure 110 in the Y direction) becomes smaller and smaller. The scaling of the spacing may be limited in order to prevent adjacent epitaxial source/drain features from merging due to the lateral growth of the source/drain features. In accordance with the embodiments of the present disclosure, the isolation features 160 (i.e., Cut-EPI features) are formed between adjacent source/drain features 126N, which may make sure that adjacent source/drain features are physically and electrically isolated from each other. Therefore, the scaling of the spacing may not be limited by the lateral growth of the source/drain features, and thus continuously scaling down the cell height of the semiconductor devices may be achieved.

In addition, the isolation features 160 cut through the portion of source/drain features 126N overhanging the isolation structure 110. Therefore, the overlapping area between the source/drain features and the final gate stack may be reduced. Therefore, the total cell parasitic capacitance of the resulting semiconductor device may be reduced, and thus the performance (e.g., speed) of the resulting semiconductor device may be enhanced.

FIG. 3A is a modification of the semiconductor structure of FIG. 2K-4, in accordance with some embodiments. The embodiments of FIG. 3A are similar to the embodiments of FIGS. 2A to 2K-3 where like reference numerals indicate like elements formed by like processes except that the isolation feature 160 is offset toward one of the active regions 104N. The extension line 160S2 of one of the sidewalls of the isolation feature 160 penetrates through between the fin spacer layers 119, in accordance with some embodiments.

FIG. 3B is a modification of the semiconductor structure of FIG. 2K-4, in accordance with some embodiments. The embodiments of FIG. 3B are similar to the embodiments of FIGS. 2A to 2K-3 where like reference numerals indicate like elements formed by like processes except that the isolation feature 160 has a greater dimension in the Y direction. The dimension D1 of the isolation feature 160 in the Y direction is greater than the spacing between adjacent active regions 104N, in accordance with some embodiments. The extension lines 106S1 and 160S2 of the sidewalls (or edges) of the isolation feature 160 penetrate through the lower fin elements 103P, in accordance with some embodiments. That is, the isolation feature 160 vertically overlaps the lower fin elements 103P, in accordance with some embodiments.

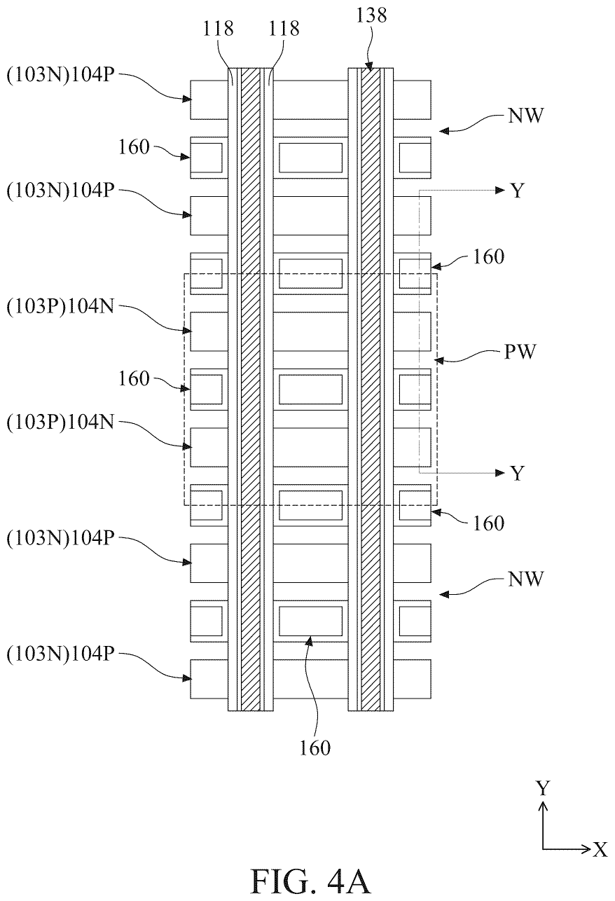

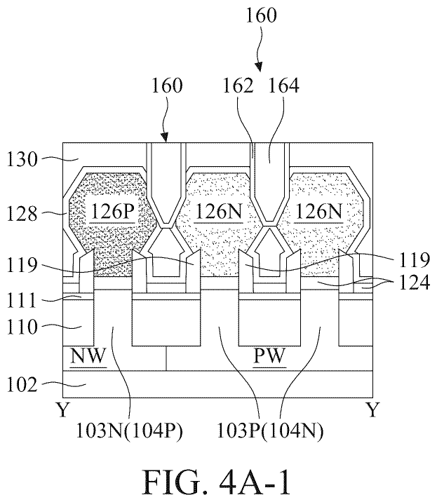

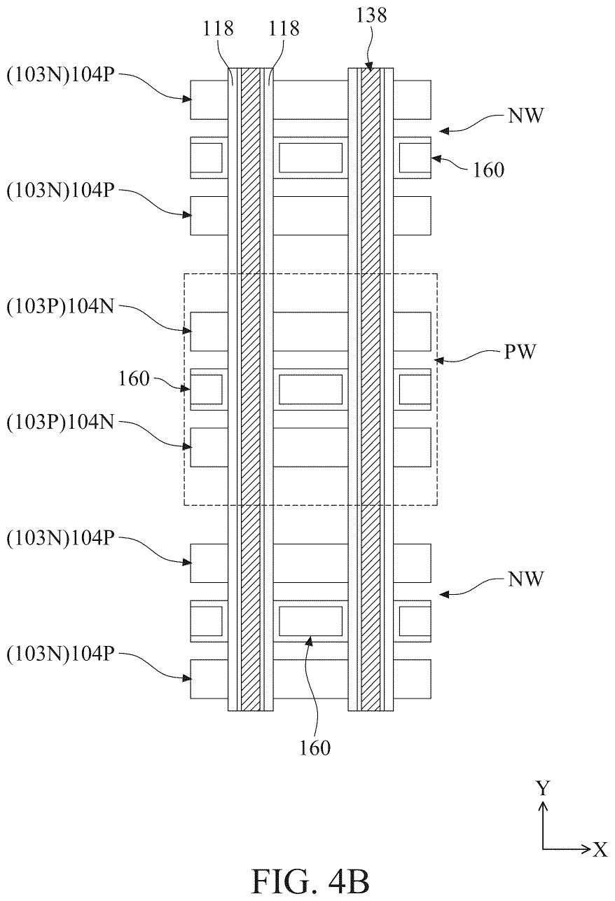

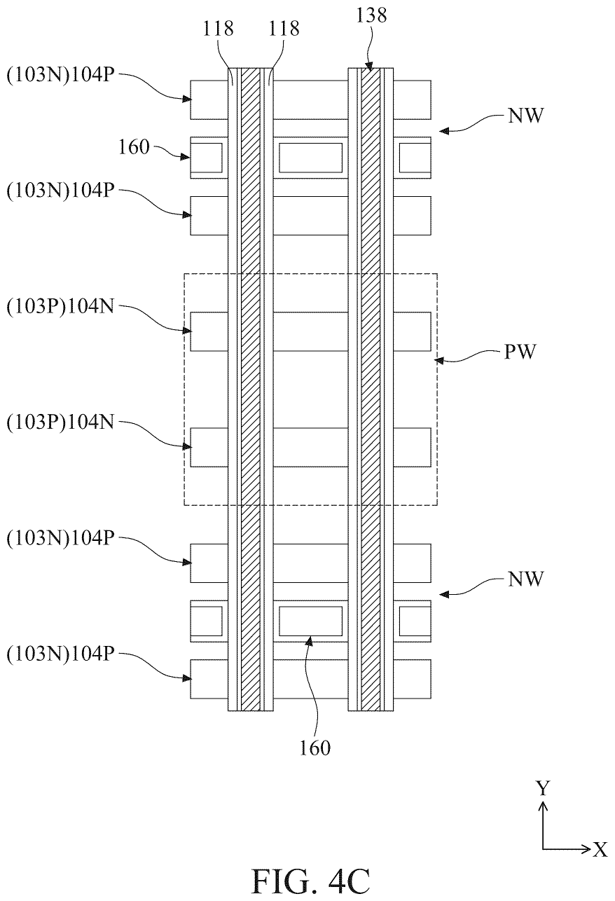

FIG. 4A is a top view illustrating a semiconductor structure 100, FIG. 4A-1 is a cross-sectional view of the semiconductor structure corresponding to line Y-Y of FIG. 4A, in accordance with some embodiments. The embodiments of FIGS. 4A and 4A-1 are similar to the embodiments of FIGS. 2A to 2K-3 where like reference numerals indicate like elements formed by like processes except that the isolation features 160 are formed within the n-type wells NW, within the p-type well PW and on the boundaries between the n-type wells NW and the p-type well PW.

FIG. 4B is a top view illustrating a semiconductor structure 100. The embodiments of FIG. 4B are similar to the embodiments of FIGS. 2A to 2K-3 where like reference numerals indicate like elements formed by like processes except that the isolation features 160 are formed within the n-type wells NW and within the p-type well PW.

FIG. 4C is a top view illustrating a semiconductor structure 100. The embodiments of FIG. 4C are similar to the embodiments of FIGS. 2A to 2K-3 where like reference numerals indicate like elements formed by like processes except that the isolation features 160 are formed within the n-type wells NW. Although not shown in FIGS. 4A, 4B and 4C, the contact structures 168 may be formed according to circuit design requirements.

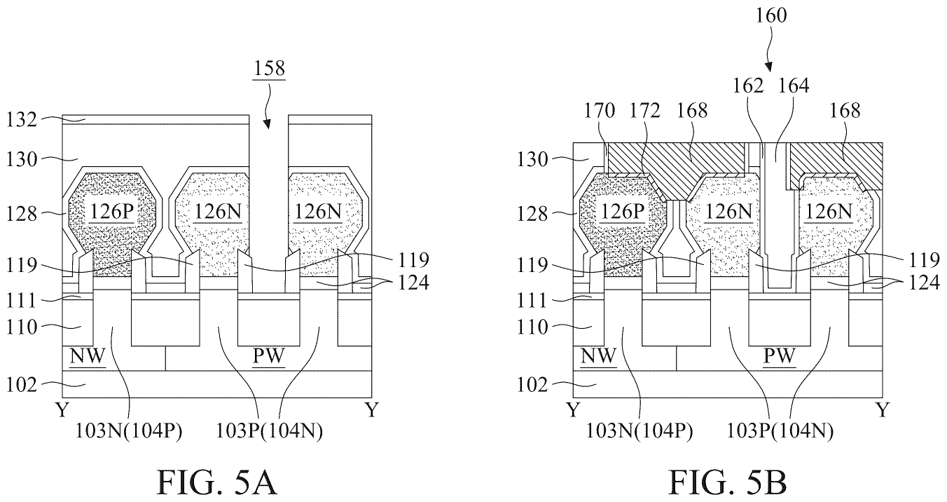

FIGS. 5A and 5B are cross-sectional views illustrating the formation of a semiconductor structure 100 at various intermediate stages corresponding to cross-section Y-Y, in accordance with some embodiments of the disclosure. The embodiments of FIGS. 5A and 5B are similar to the embodiments of FIGS. 2A to 2K-3 where like reference numerals indicate like elements formed by like processes except that the bottom of the cut openings 158 extends to the protection layer 111.

Continuing from FIGS. 2I-1 to 2I-4, the cut openings 158 are formed to extend through the interposing layer 124, as shown in FIG. 5A, in accordance with some embodiments. The protection layer 111 is exposed from the cut opening 158, in accordance with some embodiments. The steps described above in FIGS. 2J to 2K-3 are performed, thereby forming the isolation features 160 and the contact structures 168, as shown in FIG. 5B, in accordance with some embodiments. In some embodiments, the surface of the source/drain features 126N interfaced with the isolation features 160 may have different roughness from (e.g., higher than) the surface of the source/drain features 126N interfaced with the isolation features 160 interfaced with the contact etching stop layer 128.

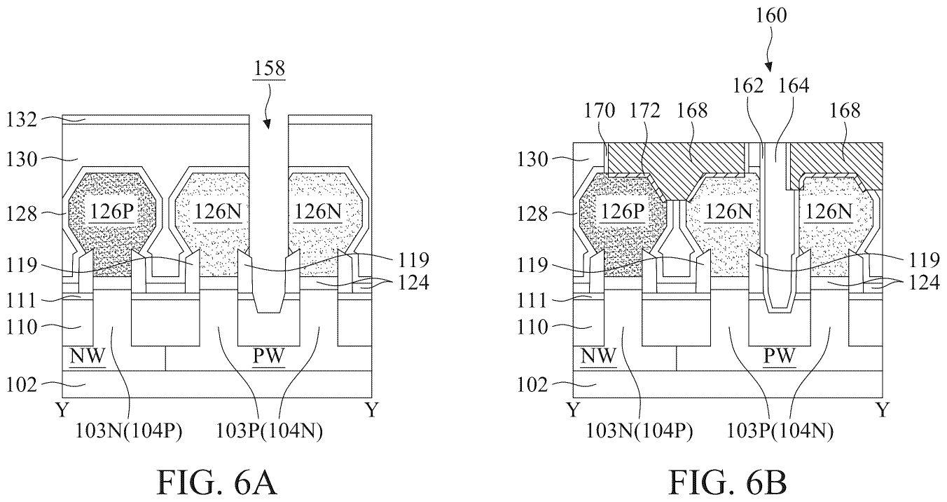

FIGS. 6A and 6B are cross-sectional views illustrating the formation of a semiconductor structure 100 at various intermediate stages corresponding to cross-section Y-Y, in accordance with some embodiments of the disclosure. The embodiments of FIGS. 6A and 6B are similar to the embodiments of FIGS. 2A to 2K-3 where like reference numerals indicate like elements formed by like processes except that the bottom of the cut openings 158 extends into the isolation structure 110.

Continuing from FIGS. 2I-1 to 2I-4, the cut openings 158 are formed to extend through the protection layer 111 and into the isolation structure 110, as shown in FIG. 6A, in accordance with some embodiments. The steps described above in FIGS. 2J to 2K-3 are performed, thereby forming the isolation features 160 and the contact structures 168, as shown in FIG. 6B, in accordance with some embodiments.

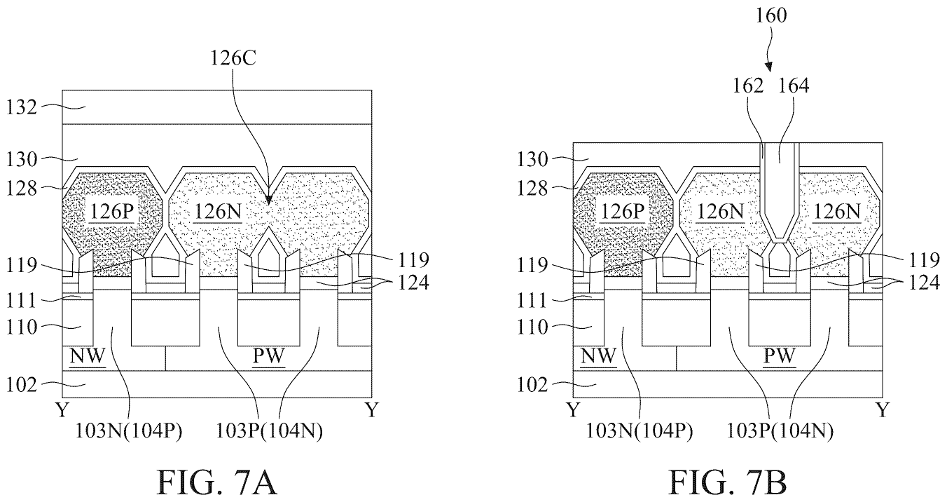

FIGS. 7A and 7B are cross-sectional views illustrating the formation of a semiconductor structure 100 at various intermediate stages correspond to cross-section Y-Y, in accordance with some embodiments of the disclosure. The embodiments of FIGS. 7A and 7B are similar to the embodiments of FIGS. 2A to 2K-3 where like reference numerals indicate like elements formed by like processes except that the source/drain features 126N are merged with each other.

Continuing from FIGS. 2C-1 to 2C-4, the adjacent n-type source/drain features 126N are grown to merge to each other, thereby forming a merged source/drain feature, as shown in FIG. 7A, in accordance with some embodiments. The merged source/drain feature has a connecting portion 126C, in accordance with some embodiments. The connecting portion 126C is the portion of the merged source/drain feature having the minimum thickness (the dimension in the Z direction), in accordance with some embodiments.

The n-type source/drain features 126N are separate from and the p-type source/drain features 126P adjacent thereto by the contact etching stop layer 128, because the source/drain mask layer is formed to cover the n-type source/drain features 126N while the source/drain features 126P are grown, in accordance with some embodiments.

The steps described above in FIGS. 2D-1 to 2K-3 are performed, thereby forming the final gate stacks 138, the isolation features 160 and the contact structures 168, as shown in FIG. 7B, in accordance with some embodiments. The isolation feature 160 cuts through the merged source/drain feature 126N into two separate source/drain features 126N, in accordance with some embodiments. In some embodiments, the isolation feature 160 is equidistant to the active regions 104N and 104N, and penetrates through the connecting portion 126C.

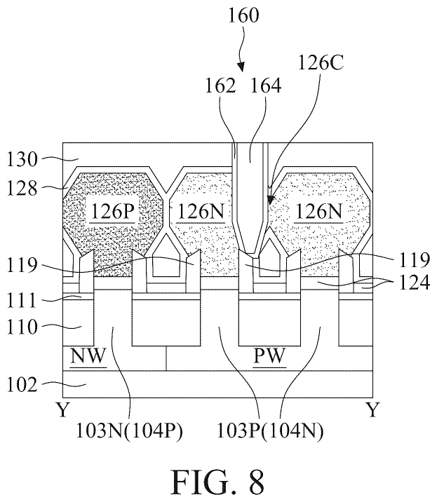

FIG. 8 is a modification of the semiconductor structure of FIG. 7B, in accordance with some embodiments. The embodiments of FIG. 8 are similar to the embodiments of FIGS. 7A and 7B where like reference numerals indicate like elements formed by like processes except that the isolation feature 160 is offset toward one of the active regions 104N. After the isolation features 160 are formed, the connecting portion 126C remains on one of the source/drain features 126N, in accordance with some embodiments. The source/drain features 126N have different widths (i.e., the dimension in the Y direction), in accordance with some embodiments.

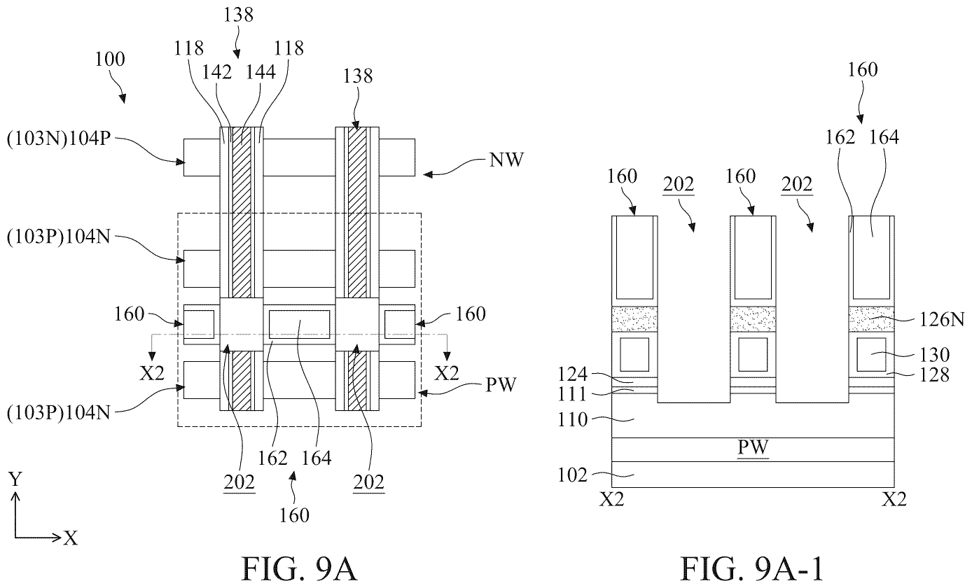

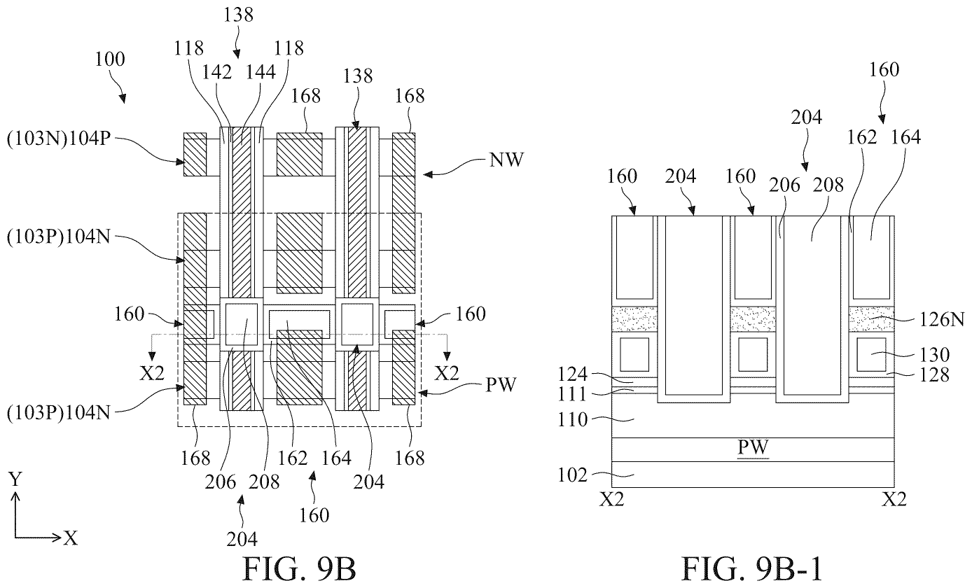

FIGS. 9A through 9B-1 are schematic views illustrating the formation of a semiconductor structure 100 at various intermediate stages, in accordance with some embodiments of the disclosure. FIGS. 9A and 9B are top views of the semiconductor structure 100, and FIGS. 9A and 9B correspond to cross-section X2-X2. The embodiments of FIGS. 9A through 9B-1 are similar to the embodiments of FIGS. 2A to 2K-3 where like reference numerals indicate like elements formed by like processes except that the gate-cut features 204 are formed.

After the isolation features 160 are formed, the semiconductor structure 100 is patterned using photolithography and etching processes to form cut openings 202 through the final gate stacks 138 and the gate spacer layers 118, as shown in FIGS. 9A and 9A-1, in accordance with some embodiments. The cut openings 202 extend into the isolation structure 110, in accordance with some embodiments. The cut openings 202 may be also referred to as cut metal gate (CMG) patterns.

The photolithography process includes forming a photoresist (not shown) such as by using spin-on coating, and then patterning the photoresist to have opening patterns corresponding to the cut openings 202 by exposing the photoresist to light using an appropriate photomask (or reticle). Exposed or unexposed portions of the photoresist may be removed depending on whether a positive or negative resist is used. The photoresist can be removed in an ashing or wet strip process, for example. In alternative embodiments, a hard mask layer (not shown) may be formed on semiconductor structure 100. The hard mask layer may be etched using a patterned photoresist layer, which may be formed by the photolithography described above, thereby having the opening patterns corresponding to the cut openings 202.

The final gate stacks 138 are cut through by the cut openings 202 into several segments which are physically and electrically isolated from each other, in accordance with some embodiments. In some embodiments, along the X direction, the cut openings 202 are formed between the isolation features 160. In some embodiments, the sidewalls of the isolation features 160 are exposed from the cut openings 202. The cut openings 202 further expose the contact etching stop layer 128 and the source/drain features 126N, in accordance with some embodiments

Gate-cut features 204 are formed in the cut openings 202, as shown in FIGS. 9B and 9B-1, in accordance with some embodiments. The formation of the gate-cut features 204 includes depositing a dielectric liner 206 along the semiconductor structure 100 to partially fill the cut openings 202, depositing a dielectric bulk layer 208 on the dielectric liner 204 to overfill the gate-cut opening 202, and planarizing the dielectric liner 206 and the dielectric bulk layer 208, in accordance with some embodiments.

The dielectric liner 206 and the dielectric bulk layer 208 are made of dielectric material, such as silicon nitride (SiN), silicon oxynitride (SiON), silicon oxide (SiO₂), oxygen-doped silicon carbide (SiC:O), silicon carbonitride (SiCN), oxygen-doped silicon carbonitride (Si(O)CN), silicon carbide (SiC), or another suitable dielectric material. In some embodiments, the dielectric liner 206 and the dielectric bulk layer 208 are made of different materials and have different dielectric constant values. For example, the dielectric liner 206 is made of SiN, and the dielectric bulk layer 208 is made of SiO. In some embodiments, the dielectric liner 206 has a higher dielectric constant than the dielectric bulk layer 208. Although not shown in FIGS. 9B and 9B-1, contact structures 168 may be formed according to circuit design requirements after the gate-cut features 204 are formed.

In some embodiments, the gate-cut features 204 abuts the isolation features 160. In some embodiments, the gate-cut features 204 and the isolation features 160 are arranged along the X direction over the isolation structure 110. In some embodiments, the dimension of the gate-cut features 204 in the Y direction is greater than the dimension of the isolation features 160 in the Y direction. In some other embodiments, the dimension of the gate-cut features 204 in the Y direction is equal to or less than the dimension of the isolation features 160 in the Y direction. In some embodiments, the thickness (i.e., the dimension in the Z direction) is greater than the thickness of the isolation features 160.

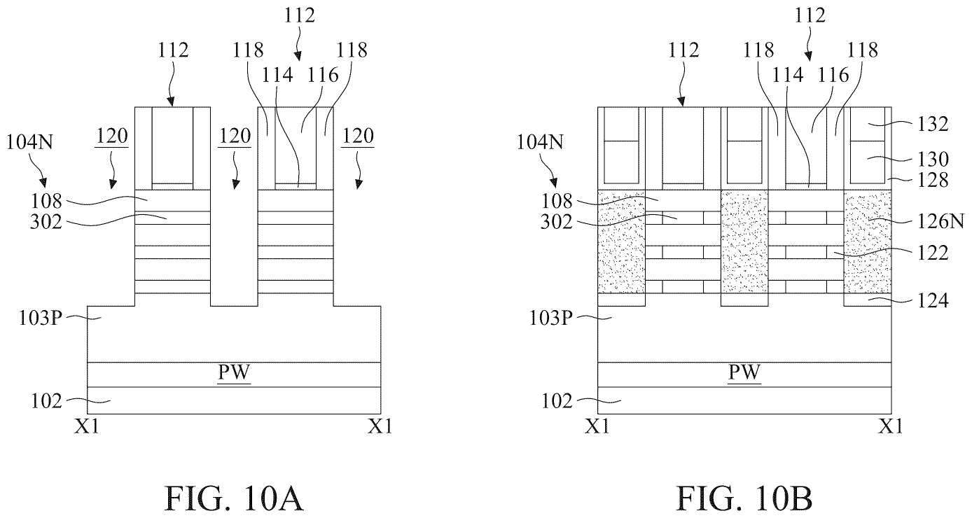

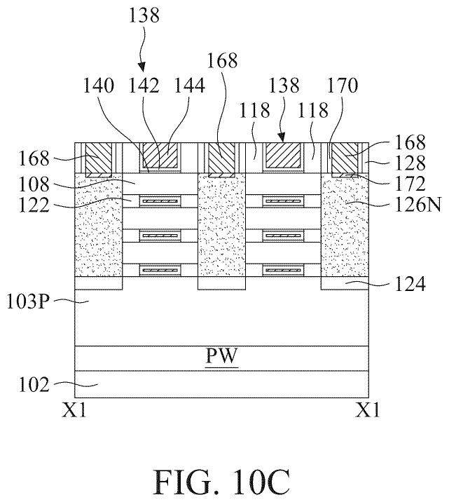

FIGS. 10A, 10B and 10C are cross-sectional views illustrating the formation of a semiconductor structure 100 corresponding to cross-section X1-X1 at various intermediate stages, in accordance with some embodiments. The embodiments of FIGS. 10A, 10B and 10C are similar to the embodiments of FIGS. 2A to 2K-3 where like reference numerals indicate like elements formed by like processes except that a Disposable Oxide Interposer (DOI) process is used.

After the source/drain recesses 120 are formed, the first semiconductor layers 106 are replaced with dielectric interposers 302, as shown in FIG. 10A, in accordance with some embodiments. The dielectric interposers 302 are made of silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In an embodiment, the dielectric interposers 302 are made of SiO.

The formation of the dielectric interposers 302 includes performing an etching process to remove the first semiconductor layers 106, thereby forming gaps, in accordance with some embodiments. The etching process includes an isotropic etching process such as dry chemical etching, remote plasma etching or wet chemical etching, or a combination thereof. The formation of the dielectric interposers 302 further includes depositing a dielectric material over the semiconductor structure 100 to overfill the gaps, and performing an etching process to etch away the dielectric material outside the gaps, in accordance with some embodiments.

The dielectric interposers 302 are laterally recessed using and etching process, and then inner spacer layers 122 are formed to abut the recessed side surfaces of the first dielectric interposers 302, as shown in FIG. 10B, in accordance with some embodiments. The steps described above in FIGS. 2C-1 to 2C-4 are performed, thereby forming the interposing layers 124, the source/drain features 126N and 126P, the contact etching stop layer 128, the interlayer dielectric layer 130 and the dielectric cap layer 132, as shown in FIG. 10B, in accordance with some embodiments.

One or more etching processes are performed to remove the dummy gate structure 112 to form gate trenches and remove the dielectric interposers 302 to form gaps, in accordance with some embodiments. The etching selectivity (e.g., greater than 10000) between the dielectric interposers 302 (e.g., SiO) and the second semiconductor layers 108 (e.g., Si) is much greater than the etching selectivity (e.g., about 170) between the first semiconductor layers 106 (e.g., SiGe) and the second semiconductor layers 108 (e.g., Si), in accordance with some embodiments. The DOI process may reduce the loss of the second semiconductor layers 108 in the channel-releasing process, and thus the nanostructures 109 may have a greater thickness. The performance (e.g., on-state current) of the resulting semiconductor may be improved. The steps described above in FIGS. 2E to 2K-3 are performed, thereby forming the final gate stacks 138, the isolation features 160 and the contact structures 168, as shown in FIG. 10C, in accordance with some embodiments.

As described above, the semiconductor structure includes isolation features 160 which separate the adjacent source/drain features 126N and/or 126P from each other. Therefore, the scaling of the spacing between adjacent active regions 104N and/or 104P may not be limited by the lateral growth of the source/drain features, and thus continuously scaling down the cell height of the semiconductor devices may be achieved without degrading the manufacturing yield of the semiconductor devices.

In addition, the isolation features 160 cut through the portion of source/drain features 126N overhanging the isolation structure 110. Therefore, the overlapping area between the source/drain features and the final gate stack may be reduced. Therefore, the total cell parasitic capacitance of the resulting semiconductor device may be reduced, and thus the performance (e.g., speed) of the resulting semiconductor device may be enhanced.

Embodiments of a semiconductor structure and the method for forming the same may be provided. The semiconductor structure includes an isolation feature penetrating through an interlayer dielectric layer and interposed between a first source/drain feature and a second source/drain feature. The isolation feature may separate the adjacent source/drain features from each other. Therefore, continuously scaling down the cell height of the semiconductor devices may be achieved without degrading the manufacturing yield of the semiconductor devices.

In some embodiments, a method for forming a semiconductor structure is provided. The method includes forming a first active region and a second active region over a substrate. The method includes forming a first source/drain feature and a second source/drain feature on the first active region and the second active region, respectively. The method includes forming a dielectric layer to cover the first source/drain feature and the second source/drain feature. The method includes forming a gate stack across the first active region and the second active region. The method includes patterning the dielectric layer to form an opening between the first source/drain feature and the second source/drain feature. The method includes forming an isolation feature in the opening, and forming a contact structure through the dielectric layer and on the first source/drain feature. An electrical conductivity of the contact structure is greater than an electrical conductivity of the first source/drain feature.

In some embodiments, a method for forming a semiconductor structure is provided. The method includes forming a first active region and a second active region over a substrate. The method includes forming an isolation structure between lower portions of the first active region and the second active region. The method includes forming a first source/drain feature and a second source/drain feature on the first active region and the second active region, respectively. The method includes forming a contact etching stop layer to cover the first source/drain feature and the second source/drain feature. A dielectric constant of the contact etching stop layer is higher than a dielectric constant of the isolation structure. The method further includes forming an interlayer dielectric layer over the contact etching stop layer. The method further includes forming a first gate stack and a second gate stack to surround the first active region and the second active region. The method further includes forming an etch mask over the interlayer dielectric and the first and second gate stacks. The etch mask includes protection features covering top surfaces of the first and second gate stacks. The method further includes etching the interlayer dielectric layer, the contact etching stop layer and at least one of the first source/drain feature and the second source/drain feature using the etch mask to form a first opening over the isolation structure, and forming a first isolation feature in the first opening

etching the interlayer dielectric layer, the contact etching stop layer, and at least one of the first source/drain feature and the second source/drain feature to form a first opening over the isolation structure. The method further includes forming a first isolation feature in the first opening.

In some embodiments, a semiconductor structure is provided. The semiconductor structure includes a first source/drain feature over a first fin element, a second source/drain feature over a second fin element, and a first gate stack and a second gate stack across the first fin element and the second fin element. The first fin element and the second fin element extend lengthwise along a first direction, and the first gate stack and the second gate stack extend lengthwise along a second direction that is different than the first direction. The semiconductor structure further includes a dielectric layer covering the second source/drain feature and the first source/drain feature. The semiconductor structure further includes an isolation feature interposed between the first source/drain feature and the second source/drain feature, and between the first gate stack and the second gate stack. The semiconductor structure further includes a contact structure in the dielectric layer, wherein the contact structure is electrically coupled to the first source/drain feature by way of a silicide layer. An electrical conductivity of the silicide layer is between an electrical conductivity of the contact structure and an electrical conductivity of the first source/drain feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a first active region and a second active region over a substrate;
forming a first source/drain feature and a second source/drain feature on the first active region and the second active region, respectively;
forming a dielectric layer to cover the first source/drain feature and the second source/drain feature;
forming a gate stack across the first active region and the second active region;
patterning the dielectric layer to form an opening between the first source/drain feature and the second source/drain feature;
forming an isolation feature in the opening; and
forming a contact structure through the dielectric layer and on the first source/drain feature, wherein an electrical conductivity of the contact structure is greater than an electrical conductivity of the first source/drain feature.

2. The method for forming the semiconductor structure as claimed in claim 1, wherein patterning the dielectric layer to form the opening comprises:
forming a patterned mask layer over the dielectric layer and the gate stack, wherein the patterned mask layer has a trench pattern exposing the gate stack;
forming a protection feature on the gate stack in the trench pattern; and
etching the dielectric layer.

3. The method for forming the semiconductor structure as claimed in claim 1, wherein the contact structure abuts the isolation feature.

4. The method for forming the semiconductor structure as claimed in claim 1, wherein the opening exposes a surface of the first source/drain feature and a surface of the second source/drain feature.

5. The method for forming the semiconductor structure as claimed in claim 1, wherein the first source/drain feature is merged with the second source/drain feature.

6. The method for forming the semiconductor structure as claimed in claim 1, wherein both the first source/drain feature and the second source/drain feature are doped with an n-type dopant.

7. The method for forming the semiconductor structure as claimed in claim 1, wherein the first source/drain feature is doped with an n-type dopant, and the second source/drain feature is doped with a p-type dopant.

8. The method for forming the semiconductor structure as claimed in claim 1, further comprising:
forming a gate spacer layer along a sidewall of the gate stack, wherein the opening exposes a sidewall of the gate spacer layer.

9. A method for forming a semiconductor structure, comprising:
forming a first active region and a second active region over a substrate;
forming an isolation structure between lower portions of the first active region and the second active region;
forming a first source/drain feature and a second source/drain feature on the first active region and the second active region, respectively;
forming a contact etching stop layer to cover the first source/drain feature and the second source/drain feature, wherein a dielectric constant of the contact etching stop layer is higher than a dielectric constant of the isolation structure;
forming an interlayer dielectric layer over the contact etching stop layer;
forming a first gate stack and a second gate stack to surround the first active region and the second active region;
forming an etch mask over the interlayer dielectric and the first and second gate stacks, wherein the etch mask includes protection features covering top surfaces of the first and second gate stacks;
etching the interlayer dielectric layer, the contact etching stop layer and at least one of the first source/drain feature and the second source/drain feature using the etch mask to form a first opening over the isolation structure; and
forming a first isolation feature in the first opening.

10. The method for forming the semiconductor structure as claimed in claim 9, wherein the first isolation feature includes a dielectric liner and a dielectric fill layer on the dielectric liner and made of a different material than the dielectric liner, and the dielectric fill layer is separated from the first source/drain feature and the second source/drain feature by the dielectric liner.

11. The method for forming the semiconductor structure as claimed in claim 10, wherein the dielectric liner of the first isolation feature is interfaced with the interlayer dielectric layer, the contact etching stop layer and at least one of the first source/drain feature and the second source/drain feature.

12. The method for forming the semiconductor structure as claimed in claim 9, wherein the first opening exposes an upper surface of the isolation structure.

13. The method for forming the semiconductor structure as claimed in claim 9, wherein each of the first active region and the second active region includes alternating first semiconductor layers and second semiconductor layers, and the method further comprises removing the first semiconductor layers of the first active region and the second active region.

14. The method for forming the semiconductor structure as claimed in claim 9, further comprising:
etching the first gate stack to form a second opening after forming the first isolation feature in the first opening; and
forming a second isolation feature in the second opening.

15. A semiconductor structure, comprising:
a first source/drain feature over a first fin element;
a second source/drain feature over a second fin element;
a first gate stack and a second gate stack across the first fin element and the second fin element, wherein the first fin element and the second fin element extend lengthwise along a first direction, and the first gate stack and the second gate stack extend lengthwise along a second direction that is different than the first direction,
a dielectric layer covering the second source/drain feature and the first source/drain feature;
an isolation feature interposed between the first source/drain feature and the second source/drain feature and between the first gate stack and the second gate stack; and
a contact structure in the dielectric layer and electrically coupled to the first source/drain feature by way of a silicide layer, and an electrical conductivity of the silicide layer is between an electrical conductivity of the contact structure and an electrical conductivity of the first source/drain feature.

16. The semiconductor structure as claimed in claim 15, wherein the isolation feature includes a dielectric liner and a dielectric fill layer surrounded by the dielectric liner, wherein the dielectric fill layer is separated from the first gate stack by the dielectric liner.

17. The semiconductor structure as claimed in claim 15, wherein the contact structure is interfaced with the isolation feature.

18. The semiconductor structure as claimed in claim 15, further comprising:
first and second fin spacer layers surrounding a bottom portion of the first source/drain feature, wherein an extension line of a first edge of the isolation feature passes through the second fin spacer layer.

19. The semiconductor structure as claimed in claim 18, further comprising:
third and fourth fin spacer layers surrounding a bottom portion of the second source/drain feature, wherein the second and third fin spacer layers are between the first and fourth fin spacer layers, and an extension line of a second edge of the isolation feature is between the second fin spacer layer and the third fin spacer layer.

20. The semiconductor structure as claimed in claim 15, further comprising:
a contact etching stop layer between the first source/drain feature and the dielectric layer, wherein the first source/drain feature has a sidewall, and the sidewall includes an upper portion interfaced with the isolation feature and a lower portion interfaced with the contact etching stop layer.
